(19) United States
(12) Patent Application Publication
(10) Pub. No.: US 2026/0213085 A1
(43) Pub. Date: Jul. 23, 2026

(54) AN ELECTRIC DOUBLE LAYER CAPACITOR DEVICE

(71) Applicant: CAP-XX LIMITED, New South Wales (AU)

(72) Inventors: Andrzej KUCHARZEWSKI, New South Wales (AU); Alexander BILYK, New South Wales (AU); Warren Duncan KING, New South Wales (AU); Sarkis Minas KESHISHIAN, New South Wales (AU); Pauline Eugene MICHAELS, New South Wales (AU); Julien MCCARTHY, New South Wales (AU); Thomas Keith ELLIS, New South Wales (AU)

(21) Appl. No.: 19/134,871

(22) PCT Filed: Dec. 4, 2023
(86) PCT No.: PCT/AU2023/051251

§ 371 Date: Jun. 2, 2025

(30) Foreign Application Priority Data
Dec. 2, 2022 (AU) 2022903689
Dec. 2, 2022 (AU) 2022903690

(51) Int. Cl. H01G 11/80; H01G 11/24; H01G 11/34; H01G 11/38; H01G 11/42; H01G 11/74; H01G 11/82

(52) U.S. Cl. CPC H01G 11/80; H01G 11/24; H01G 11/38; H01G 11/42; H01G 11/74; H01G 11/82; H01G 11/34

(57) ABSTRACT

An electric double layer capacitor (EDLC) device (1) for reflow soldering to a printed circuit board (PCB) (2). Device (1) includes a cylindrical thin-walled malleable aluminium housing (3) that extends between an open end (5) and a closed end (6). Housing (3) defines a circular opening (7) adjacent to end (5) and a cylindrical cavity (8) that extends away from opening (7) and which terminates at end (6). A cylindrical capacitor element (9) is received complementarily in cavity (8) and includes two carbon-based electrodes (11, 12). A separator, in the form of two elongate paper-based separator sheets (13, 14) are alternated, and spiral wound together with electrodes (11, 12). Sheets (13, 14) maintain electrodes (11, 12) in a spaced apart and opposed configuration. An electrolyte impregnates electrodes (11, 12) as well as sheets (13, 14) and is contained within cavity (6) for allowing ionic conduction between electrodes (11, 12). The electrolyte has at 1 atm a freezing point of less than 0° C. and a boiling point of more than 200° C. A sealing element, in the form of a rubber lid (15), extends over and seals opening (7). Two terminals (17, 18), in use, each extend between a first end (19) disposed in cavity (8) and a second end (20) disposed externally to cavity (8). Ends (19) are electrically connected to the respective electrodes (11, 12), and terminals (17, 18) extend through opening (7) such that ends (20) are available for electrical connection to PCB (2).

### FIELD OF THE INVENTION

The present invention relates to a supercapacitor, and in particular to an electric double layer capacitor (EDLC) device.

Embodiments of the invention have been developed as surface mount EDLC devices for use in electronic components and circuits for computing devices and will be described herein with particular reference to that application. However, it will be appreciated that the invention is not limited to such a field of use, and is applicable in broader contexts including, without limitation, to mobile devices, wearable devices, asset tracking devices, battery support devices, and others.

### BACKGROUND

Any discussion of the background art throughout the specification should in no way be considered as an admission that such art is widely known or forms part of common general knowledge in the field.

An EDLC device, which is also referred to more generally as a supercapacitor or an ultracapacitor, is a high specific capacitance device making use of high surface area opposed electrodes. Such electrodes can be carbon-based and include, for example, respective thin coatings or layers having one or more of activated carbon, carbon nanotubes, carbon black, or the like. An electrolyte is provided to allow for ionic conduction between the electrodes. When an electrical potential is applied to the electrodes, the ions in the electrolyte orientate and migrate toward the electrode of opposite polarity to define two layers of charge adjacent to those respective electrodes. Accordingly, the EDLC device defines two capacitors in series, the first being between the positive electrode and the adjacent layer of negative ions that is formed in the electrolyte, and the second being between the negative electrode and the adjacent layer of positive ions that is formed in the electrolyte.

The term “ultracapacitor” is synonymous with the term “supercapacitor” and the two are considered interchangeable in this specification.

An EDLC device will typically offer for a given weight or volume considerably more capacitance than is provided by a conventional capacitor. By way of comparison, an electrolytic capacitor may be able to provide a volumetric capacitance in the order of 1 mFcm⁻³, whereas an EDLC device may provide a volumetric capacitance in the order of 10 to 15 Fcm⁻³. Accordingly, steps have been taken to apply EDLC devices to a broader range of electronic circuits, particularly those such as microelectronic circuits used in computing devices, in which volume considerations for each electronic component in the circuit are paramount.

The mass manufacture of microelectronic circuits is increasingly automated and makes use of a reflow process to surface mount electronic components to a printed circuit board (PCB). This form of manufacture makes use of surface mount technology (SMT), and the electronic components intended for SMT manufacture are referred to in this specification as: surface mount devices (SMD); or SMT devices. The latter two terms are synonymous are considered interchangeable in this specification. It will be appreciated that a PCB may include only SMT devices, or a combination of SMT devices and non-SMT devices.

The thermal profile of a given reflow process is usually well specified. This can include, by way of example, a six-minute cycle with an initial ramp up phase from room temperature, a maintenance phase at about 160° C. for 100 seconds, a further ramp up phase which peaks at about 260° C., and a final cooldown phase. Other profiles are also used. In some reflow processes one or more extra passes through the reflow oven are required to rework parts.

It has been found that conventional EDLC devices, when subject to a thermal shock from a reflow process such as that set out above, often have relatively high failure rates or unacceptably reduced lifetimes. This problem is exacerbated for smaller EDLC devices which have less volume available for thermally protecting the sensitive internal components of the EDLC device.

In partial answer to these problems, it is known to provide an EDLC device for use in a reflow process. In this specification, EDLC devices intended for this process will be referred to as SMD EDLC devices. One known SMD EDLC device is pre-mounted to a specially formed PCB making use of a ceramic substrate (International PCT application PCT/KR2011/008979). The need for such a PCB not only adds material expense to process, but also manufacturing complexity as it involves thermocompression bonding of the metal housing to the substrate. Other alternatives include: an SMD EDLC device making use of a sulphuric acid electrolyte with a strengthened packaging to better avoid plastic deformation of the packaging during the reflow process; and other SMD EDLC devices having organic electrolytes disposed within hermetically sealed packaging that provides thermal insulation to reduce the thermal shock experienced by the sensitive internal components of the SMD EDLC device. Examples of the latter packaging include laser welded ceramics (International PCT application PCT/US2021/040625), heat welded LCP (U.S. Pat. No. 8,773,841) and other materials. The above packaging options typically involve the use of materials that: are relatively expensive, sometimes prohibitively so; require considerable additional, and often time-consuming and expensive, manufacturing steps to produce the EDLC device; and are bulky.

Accordingly, there is a need in the art for an improved EDLC device for reflow soldering to a PCB.

### SUMMARY OF THE INVENTION

It is an object of the present invention to overcome or ameliorate at least one of the disadvantages of the prior art, or to provide a useful alternative.

One embodiment provides an electric double layer capacitor (EDLC) device for reflow soldering to a printed circuit board (PCB), the device including:
a housing for defining an opening and a cavity extending away from the opening;
a substantially cylindrical capacitor element for being received in the cavity, the element including two carbon-based electrodes and a separator that is spiral wound together with the electrodes, wherein the separator maintains the electrodes in a spaced apart and opposed configuration;
an electrolyte within the cavity for allowing ionic conduction between the electrodes;
a sealing element for sealing the opening; and
two terminals, each of which extends between a first end disposed within the cavity and a second end disposed externally to the cavity, wherein: the first ends are electrically connected to the respective electrodes; and the terminals extend through the opening such that the second ends are available for electrical connection to the PCB.

In an embodiment, the PCB includes a PCB surface to which the device is to be mounted and the device includes a base having a first face for opposing the PCB surface, and the terminals extend relative to the base such that, in use, the second ends are substantially parallel with the PCB surface. In an embodiment, the terminals extend through the base. In an embodiment, the terminals extend along the base. In an embodiment, the terminals captively retain the base to the housing. In an embodiment, in use, the base is disposed between the housing and the PCB surface. In an embodiment, the base includes conductive portions that, in use, are disposed adjacent to the terminals.

In an embodiment, the sealing element provides a compression seal. In an embodiment, the housing includes a malleable sidewall that is plastically deformed to define a sealing surface for the compression seal. In an embodiment, the malleable sidewall includes aluminium, aluminium alloy or stainless steel. In an embodiment, the malleable sidewall includes a wall thickness of less than at least one of: 1 mm; 0.5 mm; 300 microns; 290 microns; 280 microns; 270 microns; 260 microns; and 250 microns. In an embodiment, the malleable sidewall includes a wall thickness of greater than at least one of: 300 microns; 350 microns; 370 microns; 380 microns; 390 microns; and 400 microns.

In an embodiment, at least one of the electrodes includes a high surface area carbon-based material. In an embodiment, the carbon-based material has a surface area of greater than or equal to 400 m²/g. In an embodiment, the carbon-based material includes one or more of: carbon particles; graphene; reduced graphene oxide; carbon nanotubes; carbon fibres; and foamed carbon. In an embodiment, the carbon particles include one or more of: activated carbon particles; and carbon black particles. In an embodiment, the carbon particles include mesoporous carbon particles.

In an embodiment, at least one of the electrodes includes a binder. In an embodiment, the binder is one or more of: carboxymethylcellulose (CMC); a salt of CMC (such a sodium carboxymethyl cellulose); polytetrafluoroethylene (PTFE); a salt of polystyrene sulfonate (PSS), such as a Group I or Group II metal salt of PSS, including magnesium polystyrene sulfonate (MgPSS), sodium polystyrene sulfonate (NaPSS), lithium polystyrene sulfonate (LiPSS), and calcium polystyrene sulfonate (CaPSS); polyvinylidene fluoride (PVDF); and a polyimide. In an embodiment, the binder includes a fluorinated polymer. In an embodiment, the binder is stable to at least 200° C.

In an embodiment, at least one of the electrodes is binder-less. In an embodiment, the at least one electrode includes one or more of: graphene; and carbon nanotubes.

In an embodiment, the electrolyte is an organic electrolyte having at 1 atm a boiling point of greater than 200° C.

In an embodiment, the EDLC device has an initial ESR (ESR₁), wherein:
the housing has a housing temperature (T_{H});
after T_{H} has followed a predetermined thermal profile, the device has a second ESR (ESR₂), wherein:

$${ESR}_{2} \geq {ESR}_{1} ; and \frac{100 * ( {ESR}_{2} - {ESR}_{1} )}{{ESR}_{1}} \leq 500 ;$$

and
the predetermined thermal profile includes a temperature threshold (T_{T}) of at least 180° C. and a threshold duration (t_{D}), where 25 seconds≤t_{D}≤40 seconds.

In an embodiment, Tr is one of: 180° C.; and 217° C.

In an embodiment, at least one of the following conditions is satisfied:

$$\frac{100 * ( {ESR}_{2} - {ESR}_{1} )}{{ESR}_{1}} \leq 300 ; \frac{100 * ( {ESR}_{2} - {ESR}_{1} )}{{ESR}_{1}} \leq 150 ;$$

$$\frac{100 * ( {ESR}_{2} - {ESR}_{1} )}{{ESR}_{1}} \leq 120 ; \frac{100 * ( {ESR}_{2} - {ESR}_{1} )}{{ESR}_{1}} \leq 100 ;$$

$$\frac{100 * ( {ESR}_{2} - {ESR}_{1} )}{{ESR}_{1}} \leq 70 ; \frac{100 * ( {ESR}_{2} - {ESR}_{1} )}{{ESR}_{1}} \leq 50 ;$$

$$\frac{100 * ( {ESR}_{2} - {ESR}_{1} )}{{ESR}_{1}} \leq 40 ; \frac{100 * ( {ESR}_{2} - {ESR}_{1} )}{{ESR}_{1}} \leq 20 ;$$

$$\frac{100 * ( {ESR}_{2} - {ESR}_{1} )}{{ESR}_{1}} \leq 15 ; \frac{100 * ( {ESR}_{2} - {ESR}_{1} )}{{ESR}_{1}} \leq 10 ;$$

$$\frac{100 * ( {ESR}_{2} - {ESR}_{1} )}{{ESR}_{1}} \leq 5 ; \frac{100 * ( {ESR}_{2} - {ESR}_{1} )}{{ESR}_{1}} \leq 2 ; and$$

$$\frac{100 * ( {ESR}_{2} - {ESR}_{1} )}{{ESR}_{1}} \leq 1.$$

In an embodiment, T_{T}=180° C. and one or more of the following conditions are satisfied:

$$\frac{100 * ( {ESR}_{2} - {ESR}_{1} )}{{ESR}_{1}} \leq 50 ; \frac{100 * ( {ESR}_{2} - {ESR}_{1} )}{{ESR}_{1}} \leq 20 ;$$

$$\frac{100 * ( {ESR}_{2} - {ESR}_{1} )}{{ESR}_{1}} \leq 15 ; \frac{100 * ( {ESR}_{2} - {ESR}_{1} )}{{ESR}_{1}} \leq 10$$

$$\frac{100 * ( {ESR}_{2} - {ESR}_{1} )}{{ESR}_{1}} \leq 5 ; \frac{100 * ( {ESR}_{2} - {ESR}_{1} )}{{ESR}_{1}} \leq 2 ; and$$

$$\frac{100 * ( {ESR}_{2} - {ESR}_{1} )}{{ESR}_{1}} \leq 1.$$

In an embodiment, the EDLC device has a rated voltage of between 2 to 4 Volts. In an embodiment, the capacitor element defines at least one capacitor cell, wherein, in use, the cell is exposed to the rated voltage. In an embodiment, the EDLC device has a rated voltage of at least three volts and

$$\frac{100 * ( {ESR}_{2} - {ESR}_{1} )}{{ESR}_{1}} \leq 50.$$

In an embodiment, the maximum value for T_{H} during the predetermined thermal profile is Tₘₐₓ, where Tₘₐₓ≥T_{T} and at least one of the following conditions is satisfied: Tₘₐₓ≤260° C.; Tₘₐₓ≤250° C.; Tₘₐₓ≤240° C.; Tₘₐₓ≤230° C.; Tₘₐₓ≤220° C.; Tₘₐₓ≤210° C.; and Tₘₐₓ≤200° C.

In an embodiment, at least one of the electrodes includes a mixture of activated carbon particles and conducting carbon particles. In an embodiment, the carbon particles include one or more of: mesoporous carbon particles; and microporous carbon particles.

In an embodiment, the at least one electrode includes carbon nanotubes which are entangled.

The electrolyte may be any suitable electrolyte. In one embodiment, the electrolyte comprises an organic salt (such as an ionic liquid) or comprises an organic salt (solid or liquid) as a solution in a neutral organic compound/solvent. Although references herein may be to a singular salt or a singular organic compound/solvent, it will be understood throughout this disclosure that a single electrolyte may comprise one or more organic salts and may comprise none, one, or two or more neutral organic compounds/solvents.

In an embodiment, the electrolyte comprises at least one of: at least one salt; and at least one neutral compound. In one embodiment, the electrolyte is an organic electrolyte. In one embodiment, the organic electrolyte comprises an organic salt. In one embodiment, the organic electrolyte comprises two or more organic salts. In an embodiment, the electrolyte has a boiling point of 210° C. or more, 220° C. or more, 230° C. or more, 240° C. or more, or 250° C. or more, at 1 atm. In an embodiment, the electrolyte has a freezing point of −10° C. or lower; −20° C. or lower, −30° C. or lower, or −40° C. or lower, at 1 atm.

In one embodiment, the electrolyte is immiscible with the binder used in the electrode. In another embodiment the electrolyte is immiscible with the binder at temperatures of 200° C. or higher, 210° C. or higher, 220° C. or higher, 240° C. or higher, 250° C. or higher, or 260° C. or higher.

In an embodiment, the neutral compound is a neutral organic compound. The neutral organic compound may be a liquid or a solid at room temperature, such as at 20° C. and 1 atm. It will be understood that when used, the neutral organic compound acts as a solvent, and may therefore alternatively be referred to as a neutral organic solvent. The neutral organic solvent preferably has certain properties suitable for solvating the organic salt(s) (which in some embodiments are ionic liquid(s)). In one embodiment, neutral organic solvent is a liquid, such as a liquid aprotic solvent, in which the organic salt is mixed or dissolved. In another embodiment, such as where the neutral organic solvent is a solid at 20° C. and 1 atm, the organic solvent may be heated above its melting point such that it is in the liquid state when the organic salt is mixed or dissolved in it. In one embodiment, the neutral organic compound is an aprotic organic solvent. In another embodiment, the neutral organic compound is a polar aprotic organic solvent.

In one embodiment, the neutral organic compound is a polar aprotic organic solvent that has a freezing point of less than 60° C. and a boiling point of more than 150° C., 160° C., 180° C., 200° C., 220° C., 240° C. or 260° C.

In an embodiment, the at least one neutral organic compound or polar aprotic organic solvent is selected from: a linear or cyclic carbonate ester (R—O—C(═O)—O—R′), a cyclic lactone (—C(═O)—O—), or a linear or cyclic sulfone (R—S(═O)2-R′). In an embodiment, the polar aprotic solvent is a linear carbonate. In an embodiment, the linear carbonate is diethyl carbonate. In an embodiment, the polar aprotic solvent is a cyclic carbonate ester having the chemical structure:

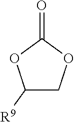

where R⁹ is: H, CH₃, a fluorinated methyl group; or F. In an embodiment, the cyclic carbonate ester includes at least one C—F bond.

In an embodiment, the at least one neutral organic compound or polar aprotic solvent is a linear or cyclic sulfone. In an embodiment, the sulfone has a linear structure as follows:

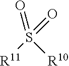

where R¹⁰ and R¹¹ are each independently, a C₁-C₄ alkyl group. In one embodiment, R¹⁰ and R¹¹ are the same. In an embodiment, R¹⁰ and R¹¹ are both ethyl groups. In an embodiment, R¹⁰ and R¹¹ are different alkyl groups.

In an embodiment, the sulfone has a cyclic structure as follows:

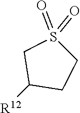

where R¹² is H or CH₃. In an embodiment, the sulfone is sulfolane.

In an embodiment, the at least one neutral organic compound or polar aprotic solvent is a lactone. In an embodiment, the cyclic lactone is gamma-butyrolactone.

In an embodiment, the salt is an organic salt. In one embodiment, the organic electrolyte comprises two or more organic salts dissolved in an organic or polar aprotic organic solvent, or two or more organic salts dissolved in a mixture of two or more organic or polar aprotic organic solvents.

In an embodiment, the organic salt includes a cation and an anion. In an embodiment, the cation includes a quaternary ammonium cation. In an embodiment, the quaternary ammonium cation has the chemical structure:

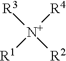

where R¹, R², R³ and R⁴ are each alkyl substituents. In an embodiment, R¹, R², R³ and R⁴ are each, independently, straight chained or branched C₁-C₇ alkyl groups. In an embodiment, R¹, R², R³ and R⁴ are each, independently, straight chained or branched C₁-C₄ alkyl groups. In an embodiment, R¹, R², R³ and R⁴ are each, independently, straight chained or branched C₁-C₂ alkyl groups.

In an embodiment, R¹ is different to at least one of R², R³ and R⁴. In an embodiment, R¹, R², R³ and R⁴ are different to each other.

In an embodiment, the quaternary ammonium cation has the chemical structure:

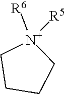

where R⁵ and R⁶ are each alkyl substituents. In an embodiment, R⁵ and R⁶ are each, independently, straight chained or branched C₁-C₇ alkyl groups. In an embodiment, R⁵ is different to R⁶. In an embodiment, the quaternary ammonium cation is a spiro-bicyclic compound in which the common atom in the spiro structure is nitrogen. In an embodiment, the spiro-bicyclic compound is spiro-bispyrrolidinium (SBP). In an embodiment, the quaternary ammonium cation is a heterocyclic nitrogen-containing cation.

In an embodiment, the anion is one or more of a borate, a phosphate and a sulfonylimide. In an embodiment, the anion is one or more of tetrafluoroborate (TFB), tetracyanoborate, fluorotricyanoborate, difluorodicyanoborate, trifluorocyanoborate, bis(oxalato) borate and difluoro (oxalato) borate. In an embodiment, the anion is one or more of bis(fluorosulfonyl)imide (FSI) and bis(trifluoromethylsulfonyl)imide (TFSI).

In another embodiment, the organic salt is a liquid at or around room temperature, referred to herein as an ionic liquid. Accordingly, in an embodiment, the organic salt is an ionic liquid. In one embodiment, the ionic liquid has a melting point of from 0° C. to 100° C. at 1 atm. In one embodiment, the ionic liquid has a thermal decomposition temperature of: 210° C. or more; 220° C. or more; 230° C. or more; 240° C. or more; and 250° C. or more, all at 1 atm. In another embodiment, the organic salt is a solid at 20° C. and 1 atm.

In an embodiment, the housing is formed at least substantially from a metal. In an embodiment, the metal includes aluminium, aluminium alloy or a stainless-steel alloy.

In an embodiment, the cavity is substantially cylindrical and complementarily receives the capacitor element. In an embodiment, the housing includes: a substantially cylindrical first sidewall that extends axially between a first end and a second end, wherein the first end defines the opening; and a substantially circular second sidewall that extends over the second end. In an embodiment, the first sidewall is thin and malleable. In an embodiment, the first sidewall has a wall thickness of less than 1 mm. In an embodiment, the first sidewall has a wall thickness of less than 0.5 mm. In an embodiment, the first sidewall and the second sidewall are integrally formed.

In an embodiment, the separator includes one or more porous separator sheets which each contain at least one of: polytetrafluoroethylene (PTFE); cellulose fibres; polyacrylonitrile fibres; aramid fibres; glass fibres; and polyethyleneterphthatlate (PET).

In an embodiment, the separator has a melting point of: 200° C. or more; 220° C. or more; 230° C. or more; 240° C. or more; and 250° C. or more.

Another embodiment provides an electric double layer capacitor (EDLC) device for reflow soldering to a printed circuit board (PCB), the device including:
a housing for defining an opening and a cavity that extends away from the opening;
a substantially cylindrical capacitor element for being received in the cavity, the element including two carbon-based electrodes and a separator that is spiral wound together with the electrodes, wherein the separator maintains the electrodes in a spaced apart and opposed configuration;
an electrolyte within the cavity for allowing ionic conduction between the electrodes, the electrolyte having at 1 atm a freezing point of 0° C. or less and a boiling point of 200° C. or more;
a sealing element for sealing the opening; and
two terminals, each of which extends between a first end disposed in the cavity and a second end disposed externally to the cavity, wherein: the first ends are electrically connected to the respective electrodes; and the terminals extend through the opening such that the second ends are available for electrical connection to the PCB.

Another embodiment provides an electric double layer capacitor (EDLC) device for reflow soldering to a printed circuit board (PCB), the device including:
a housing for defining an opening and a cavity that extends away from the opening;
a capacitor element for being received in the cavity, the element including two carbon-based electrodes and a separator for maintaining the electrodes in a spaced apart and opposed configuration;
an electrolyte within the cavity for allowing ionic conduction between the electrodes, the electrolyte having at 1 atm a freezing point of 0° C. or less and a boiling point of 200° C. or more;
a sealing element for providing a compression seal for sealing the opening; and
two terminals, each of which extends between a first end disposed in the cavity and a second end disposed externally to the cavity, wherein: the first ends are electrically connected to the respective electrodes; and the terminals extend through the opening such that the second ends are available for electrical connection to the PCB.

Another embodiment provides an electric double layer capacitor (EDLC) device for reflow soldering to a printed circuit board (PCB), the device including:
a malleable housing for defining an opening and a cavity extending away from the opening;
a capacitor element for being received in the cavity, the element including two carbon-based electrodes, and a separator that is spiral wound together with the electrodes, wherein the separator maintains the electrodes in a spaced apart and opposed configuration;
an electrolyte within the cavity for allowing ionic conduction between the electrodes;
a sealing element for sealing the opening; and
two terminals, each of which extend between respective first ends for locating within the cavity and respective second ends for locating externally to the cavity, wherein: the first ends are electrically connected to respective electrodes; and the terminals extend through the opening such that the second ends are available for electrical connection to the PCB.

Another embodiment provides an electric double layer capacitor (EDLC) device for reflow soldering to a printed circuit board (PCB), the device including:
a housing having a high thermal conductivity for defining an opening and a cavity extending away from the opening;
a capacitor element for being received in the cavity, the element including two carbon-based electrodes and a separator that is spiral wound together with the electrodes, wherein the separator maintains the electrodes in a spaced apart and opposed configuration;
an electrolyte within the cavity for allowing ionic conduction between the electrodes;
a sealing element for sealing the opening; and
two terminals, each of which extend between respective first ends for locating within the cavity and respective second ends for locating externally to the cavity, wherein: the first ends are electrically connected to respective electrodes; and the terminals extend through the opening such that the second ends are available for electrical connection to the PCB.

Another embodiment provides an electric double layer capacitor (EDLC) device for reflow soldering to a printed circuit board (PCB), the device including:
a substantially cylindrical housing for defining an opening and a cavity that extends away from the opening;
a capacitor element for being received in the cavity, the element including two carbon-based electrodes and a separator that is spiral wound together with the electrodes, wherein the separator maintains the electrodes in a spaced apart and opposed configuration;
an electrolyte within the cavity for allowing ionic conduction between the electrodes, the electrolyte having at 1 atm a freezing point of 0° C. or less and a boiling point of 200° C. or more;
a sealing element for sealing the opening; and
two terminals, each of which extends between a first end disposed in the cavity and a second end disposed externally to the cavity, wherein: the first ends are electrically connected to the respective electrodes; and the terminals extend through the opening such that the second ends are available for electrical connection to the PCB.

Another embodiment provides an electric double layer capacitor (EDLC) device for reflow soldering to a printed circuit board (PCB), the device including:
a substantially cylindrical housing for defining an opening and a cavity extending away from the opening;
a capacitor element for being received in the cavity, the element including two carbon-based electrodes and a separator that is spiral wound together with the electrodes, wherein the separator maintains the electrodes in a spaced apart and opposed configuration;
an electrolyte within the cavity for allowing ionic conduction between the electrodes;
a sealing element for sealing the opening; and
two terminals, each of which extend between respective first ends for locating within the cavity and respective second ends for locating externally to the cavity, wherein: the first ends are electrically connected to respective electrodes; and the terminals extend through the opening such that the second ends are available for electrical connection to the PCB.

Another embodiment provides an electric double layer capacitor (EDLC) device for reflow soldering to a printed circuit board (PCB), the device including:
a malleable housing for defining an opening, a cavity that extends away from the opening, a sealing surface adjacent to the opening and a retention formation;
a substantially cylindrical capacitor element for being received in the cavity, the element including two carbon-based electrodes and a separator that is spiral wound together with the electrodes, wherein the separator maintains the electrodes in a spaced apart and opposed configuration;
an electrolyte within the cavity for allowing ionic conduction between the electrodes;
a sealing element for seating against the sealing surface for sealing the opening, wherein the retention formation maintains the seating of the sealing element; and
two terminals, each of which extends between a first end disposed in the cavity and a second end disposed externally to the cavity, wherein: the first ends are electrically connected to respective electrodes; and the terminals extend through the opening such that the second ends are available for electrical connection to the PCB.

In an embodiment, the electrolyte has a boiling point at 1 atm which is at least one of: 210° C. or more; 220° C. or more; 230° C. or more; 240° C. or more; and 250° C. or more.

In an embodiment, the electrolyte has a freezing point at 1 atm of at least one of: −10° C. or less; −20° C. or less; −30° C. or less; and −40° C. or less.

In an embodiment, the housing includes a substantially cylindrical first sidewall which extends along a sidewall axis. In an embodiment, the first sidewall has a wall thickness of less than 1 mm. In an embodiment, the first sidewall has a wall thickness of less than 0.5 mm. In an embodiment, the wall thickness of the first sidewall is substantially uniform. In an embodiment: the first sidewall extends along the sidewall axis between a first end and a second end; the first end defines the opening; and the housing includes a second sidewall that extends over the second end. In an embodiment, the first sidewall defines the opening and a sealing surface adjacent to the opening for engaging with the sealing element. In an embodiment, the first sidewall defines a retention formation for captively retaining the sealing element in engagement with the sealing surface. In an embodiment, the engagement of the sealing element with the sealing surface defines a compression seal. In an embodiment, the retention formation is integrally formed with the first sidewall. In an embodiment, the terminals are directly sealingly engaged with the sealing element. In an embodiment, the sealing element is unitary.

In an embodiment, the electrodes each include carbon particles. In an embodiment, the EDLC device includes a binder for providing cohesion between the particles. In an embodiment: each electrode includes a current collector for electrically connecting the carbon particles of that electrode to the respective terminal; and the binder provides adhesion between the particles of each electrode and the respective current collectors. In an embodiment, the carbon particles have an average pore size of greater than 2 nm.

In an embodiment, the electrolyte is an organic electrolyte having, at 1 atm, a freezing point of 0° C. or less and a boiling point of 200° C. or more, and which comprises at least one of: an ionic liquid; an organic solvent that includes a cyclic or linear organosulfur or sulfone compound and at least one organic salt; an organic liquid that includes a cyclic or linear carbonate ester and at least one organic salt; and an organic liquid that includes a cyclic lactone such as gamma-butyrolactone and at least one organic salt.

In an embodiment, the organosulfur is sulfolane. In an embodiment, the carbonate ester is propylene carbonate. In an embodiment, the organic solvent includes gamma-butyrolactone. In an embodiment, the organic liquid contains a tetrafluoroborate salt, such as the organic salt contains a tetrafluoroborate anion.

In an embodiment: each electrode includes a carbon-based layer and a current collector for electrically connecting the carbon-based layer to the respective terminal; the two carbon-based electrodes and the separator are spiral wound together along a winding axis; and the separator extends along the winding axis beyond the electrodes. In an embodiment, the separator extends along the winding axis beyond the electrodes to define two opposite free ends which are inclined toward the winding axis.

Another embodiment provides an electric double layer capacitor (EDLC) device for reflow soldering to a printed circuit board (PCB), the device including:
a housing for defining an opening and a cavity extending away from the opening;
a substantially cylindrical capacitor element for being received in the cavity, the element including two electrodes each containing carbon particles, a binder for providing cohesion between the particles in each binder and a separator that is spiral wound together with the electrodes, wherein the separator maintains the electrodes in a spaced apart and opposed configuration and the binder includes at least one of: carboxymethylcellulose (CMC); a salt of CMC (such a sodium carboxymethyl cellulose); polytetrafluoroethylene (PTFE); a salt of polystyrene sulfonate (PSS), such as a Group I or Group II metal salt of PSS, including magnesium polystyrene sulfonate (MgPSS), sodium polystyrene sulfonate (NaPSS), lithium polystyrene sulfonate (LiPSS), and calcium polystyrene sulfonate (CaPSS); polyvinylidene fluoride (PVDF); and a polyimide;
an electrolyte within the cavity for allowing ionic conduction between the electrodes;
a sealing element for sealing the opening; and
two terminals, each of which extends between a first end disposed within the cavity and a second end disposed externally to the cavity, wherein: the first ends are electrically connected to the respective electrodes; and the terminals extend through the opening such that the second ends are available for electrical connection to the PCB.

Another embodiment provides an electric double layer capacitor (EDLC) device for reflow soldering to a printed circuit board (PCB) having a PCB surface with two electrical pads, the device including:
a base having a first face for opposing the PCB surface and a second face opposite the first face;
a housing for defining: an opening that, in use, is opposed with the second face;
and a cavity that extends away from the opening;
a substantially cylindrical capacitor element for being received in the cavity, the element including:
two carbon-based electrodes, wherein each electrode includes carbon particles;
a porous separator that is spiral wound together with the electrodes, wherein the separator maintains the electrodes in a spaced apart and opposed configuration and includes one or more of: polytetrafluoroethylene; cellulose fibres;
polyacrylonitrile fibres; aramid fibres; and glass fibres;
an electrolyte within the cavity for allowing ionic conduction between the electrodes, the electrolyte having at 1 atm a freezing point of 0° C. or less and a boiling point of 200° C. or more;
a sealing element for providing a compression seal for sealing the opening; and
two terminals, each of which extends between a first end disposed in the cavity and a second end disposed externally to the cavity, wherein: the first ends are electrically connected to the respective electrodes; and the terminals extend through the opening and the base such that, in use, the second ends are substantially parallel with the PCB face and electrically connected to the respective pads.

Another embodiment provides an electrical device including at least one EDLC device of any one of the preceding embodiments.

Another embodiment includes a platform including any one or more of: at least one EDLC device according to any one of the above embodiments of an EDLC device; and at least one electrical device according to the above embodiment for an electrical device.

Another embodiment includes a system including one or more of: at least one EDLC device according to any one of the above embodiments of an EDLC device; at least one electrical device according to the above embodiment of an electrical device; and at least one platform according to the above embodiment of a platform.

Another embodiment includes a printed circuit board to which is reflow soldered at least one EDLC device according to any one of the embodiments above of EDLC devices.

Another embodiment includes a method of manufacturing an electric double layer capacitor (EDLC) device for reflow soldering to a printed circuit board (PCB), the method including:
(a) providing a substantially cylindrical malleable housing having an opening and a cavity that extends away from the opening;
(b) plastically deforming the housing to define a sealing surface adjacent to the opening;
(c) plastically deforming the housing to define a retention formation;
(d) spiral winding two carbon-based electrodes together with a separator to provide a substantially cylindrical capacitor element, wherein the separator maintains the electrodes in a spaced apart and opposed configuration;
(e) receiving the capacitor element in the cavity;
(f) providing an electrolyte within the cavity for allowing ionic conduction between the electrodes;
(g) providing a sealing element for seating against the sealing surface for sealing the opening, wherein the retention formation maintains the seating of the sealing element; and
(h) providing two terminals, each of which extends between a first end disposed in the cavity and a second end disposed externally to the cavity, wherein: the first ends are electrically connected to respective electrodes; and the terminals extend through the opening such that the second ends are available for electrical connection to the PCB.

In an embodiment, step (e) precedes step (b). In an embodiment, step (e) precedes step (c). In an embodiment, step (e) precedes step (f). In an embodiment, step (b) and step (c) occur contemporaneously. In an embodiment, step (b) and step (c) occur simultaneously.

Another embodiment provides a method of manufacturing an electric double layer capacitor (EDLC) device for reflow soldering to a printed circuit board (PCB) having a PCB surface with two electrical pads, the method including the steps of:
providing a base having a first face for opposing the PCB surface and a second face opposite the first face;
defining with a housing: an opening that, in use, is opposed with the second face;
and a cavity that extends away from the opening;
receiving a substantially cylindrical capacitor element for being in the cavity, the element including:

two carbon-based electrodes, wherein each electrode includes carbon particles; and
a porous separator that is spiral wound together with the electrodes, wherein the separator maintains the electrodes in a spaced apart and opposed configuration and includes one or more of: polytetrafluoroethylene; cellulose fibres; polyacrylonitrile fibres; aramid fibres; and glass fibres;
providing an electrolyte within the cavity for allowing ionic conduction between the electrodes, the electrolyte having at 1 atm a freezing point of 0° C. or less and a boiling point of 200° C. or more;
providing a compression seal with a sealing element for sealing the opening; and
providing two terminals, each of which extends between a first end disposed in the cavity and a second end disposed externally to the cavity, wherein: the first ends are electrically connected to the respective electrodes; and the terminals extend through the opening and the base such that, in use, the second ends are substantially parallel with the PCB surface and electrically connected to the respective pads.

Another embodiment provides a method of manufacturing an electric double layer capacitor (EDLC) device for reflow soldering to a printed circuit board (PCB), the method including the steps of:
defining with a housing an opening and a cavity that extends away from the opening;
receiving a substantially cylindrical capacitor element in the cavity, the element including two carbon-based electrodes and a separator that is spiral wound together with the electrodes, wherein the separator maintains the electrodes in a spaced apart and opposed configuration;
providing an electrolyte within the cavity for allowing ionic conduction between the electrodes, the electrolyte having at 1 atm a freezing point of 0° C. or less and a boiling point of 200° C. or more;
sealing the opening with a sealing element; and
providing two terminals, each of which extends between a first end disposed in the cavity and a second end disposed externally to the cavity, wherein: the first ends are electrically connected to the respective electrodes; and the terminals extend through the opening such that the second ends are available for electrical connection to the PCB.

Another embodiment provides a method of manufacturing an electric double layer capacitor (EDLC) device for reflow soldering to a printed circuit board (PCB), the method including the steps of:
defining with a housing an opening and a cavity that extends away from the opening;
receiving a capacitor element in the cavity, the element including two carbon-based electrodes and a separator for maintaining the electrodes in a spaced apart and opposed configuration;
providing an electrolyte within the cavity for allowing ionic conduction between the electrodes, the electrolyte having at 1 atm a freezing point of 0° C. or less and a boiling point of 200° C. or more;
providing a compression seal with a sealing element for sealing the opening; and
providing two terminals, each of which extends between a first end disposed in the cavity and a second end disposed externally to the cavity, wherein: the first ends are electrically connected to the respective electrodes; and the terminals extend through the opening such that the second ends are available for electrical connection to the PCB.

Another embodiment provides a method of manufacturing an electric double layer capacitor (EDLC) device for reflow soldering to a printed circuit board (PCB), the method including the steps of:
defining with a housing an opening and a cavity extending away from the opening;
receiving a substantially cylindrical capacitor element in the cavity, the element including two carbon-based electrodes and a separator that is spiral wound together with the electrodes, wherein the separator maintains the electrodes in a spaced apart and opposed configuration;
providing an electrolyte within the cavity for allowing ionic conduction between the electrodes;
sealing the opening with a sealing element; and
providing two terminals, each of which extends between a first end disposed within the cavity and a second end disposed externally to the cavity, wherein: the first ends are electrically connected to the respective electrodes; and the terminals extend through the opening such that the second ends are available for electrical connection to the PCB.

Another embodiment provides a method of manufacturing an electric double layer capacitor (EDLC) device for reflow soldering to a printed circuit board (PCB), the method including the steps of:
defining with a malleable housing an opening and a cavity extending away from the opening;
receiving a capacitor element in the cavity, the element including two carbon-based electrodes, and a separator that is spiral wound together with the electrodes, wherein the separator maintains the electrodes in a spaced apart and opposed configuration;
providing an electrolyte within the cavity for allowing ionic conduction between the electrodes;
sealing the opening with a sealing element; and
providing two terminals, each of which extend between respective first ends for locating within the cavity and respective second ends for locating externally to the cavity, wherein: the first ends are electrically connected to respective electrodes; and the terminals extend through the opening such that the second ends are available for electrical connection to the PCB.

Another embodiment provides a method of manufacturing an electric double layer capacitor (EDLC) device for reflow soldering to a printed circuit board (PCB), the method including the steps of:
defining, with a housing having a high thermal conductivity, an opening and a cavity extending away from the opening;
receiving a capacitor element in the cavity, the element including two carbon-based electrodes and a separator that is spiral wound together with the electrodes, wherein the separator maintains the electrodes in a spaced apart and opposed configuration;
providing an electrolyte within the cavity for allowing ionic conduction between the electrodes;
sealing the opening with a sealing element; and
providing two terminals, each of which extend between respective first ends for locating within the cavity and respective second ends for locating externally to the cavity, wherein: the first ends are electrically connected to respective electrodes; and the terminals extend through the opening such that the second ends are available for electrical connection to the PCB.

Another embodiment provides a method of manufacturing an electric double layer capacitor (EDLC) device for reflow soldering to a printed circuit board (PCB), the method including the steps of:
defining, with a substantially cylindrical housing, an opening and a cavity that extends away from the opening;
receiving a capacitor element in the cavity, the element including two carbon-based electrodes and a separator that is spiral wound together with the electrodes, wherein the separator maintains the electrodes in a spaced apart and opposed configuration;
providing an electrolyte within the cavity for allowing ionic conduction between the electrodes, the electrolyte having at 1 atm a freezing point of 0° C. or less and a boiling point of 200° C. or more;
sealing the opening with a sealing element; and
providing two terminals, each of which extends between a first end disposed in the cavity and a second end disposed externally to the cavity, wherein: the first ends are electrically connected to the respective electrodes; and the terminals extend through the opening such that the second ends are available for electrical connection to the PCB.

Another embodiment provides a method of manufacturing an electric double layer capacitor (EDLC) device for reflow soldering to a printed circuit board (PCB), the method including the steps of:
defining with a housing an opening and a cavity extending away from the opening;
receiving a substantially cylindrical capacitor element in the cavity, the element including two electrodes each containing carbon particles, a binder for providing cohesion between the particles in each binder and a separator that is spiral wound together with the electrodes, wherein the separator maintains the electrodes in a spaced apart and opposed configuration and the binder includes at least one of: carboxymethylcellulose (CMC); a salt of CMC (such a sodium carboxymethyl cellulose); polytetrafluoroethylene (PTFE); a salt of polystyrene sulfonate (PSS), such as a Group I or Group II metal salt of PSS, including magnesium polystyrene sulfonate (MgPSS), sodium polystyrene sulfonate (NaPSS), lithium polystyrene sulfonate (LiPSS), and calcium polystyrene sulfonate (CaPSS); polyvinylidene fluoride (PVDF); and a polyimide;
providing an electrolyte within the cavity for allowing ionic conduction between the electrodes;
sealing the opening with a sealing element; and
providing two terminals, each of which extends between a first end disposed within the cavity and a second end disposed externally to the cavity, wherein: the first ends are electrically connected to the respective electrodes; and the terminals extend through the opening such that the second ends are available for electrical connection to the PCB.

Another embodiment provides a method of manufacturing an electric double layer capacitor (EDLC) device for reflow soldering to a printed circuit board (PCB), the method including:
defining, with a substantially cylindrical housing, an opening and a cavity extending away from the opening;
receiving a capacitor element in the cavity, the element including two carbon-based electrodes and a separator that is spiral wound together with the electrodes, wherein the separator maintains the electrodes in a spaced apart and opposed configuration;
providing an electrolyte within the cavity for allowing ionic conduction between the electrodes;
sealing the opening with a sealing element; and
providing two terminals, each of which extend between respective first ends for locating within the cavity and respective second ends for locating externally to the cavity, wherein: the first ends are electrically connected to respective electrodes; and the terminals extend through the opening such that the second ends are available for electrical connection to the PCB.

Another embodiment provides a method of manufacturing an electric double layer capacitor (EDLC) device for reflow soldering to a printed circuit board (PCB), the method including the steps of:
defining, with a malleable housing, an opening, a cavity that extends away from the opening, a sealing surface adjacent to the opening and a retention formation;
receiving a substantially cylindrical capacitor element in the cavity, the element including two carbon-based electrodes and a separator that is spiral wound together with the electrodes, wherein the separator maintains the electrodes in a spaced apart and opposed configuration;
providing an electrolyte within the cavity for allowing ionic conduction between the electrodes;
seating a sealing element against the sealing surface for sealing the opening, wherein the retention formation maintains the seating of the sealing element; and
providing two terminals, each of which extends between a first end disposed in the cavity and a second end disposed externally to the cavity, wherein: the first ends are electrically connected to respective electrodes; and the terminals extend through the opening such that the second ends are available for electrical connection to the PCB.

Reference throughout this specification to “one embodiment”, “some embodiments”, “another embodiment”, “further embodiments”, “an embodiment”, or like terms, means that a particular feature, structure or characteristic described in connection with the embodiment is included in at least one embodiment of the present invention. Thus, appearances of the phrases “in one embodiment”, “in some embodiments” “in an embodiment” or in similar phrases in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

As used herein, unless otherwise specified the use of the ordinal adjectives “first”, “second”, “third”, etc., to describe a common object, merely indicate that different instances of like objects are being referred to, and are not intended to imply that the objects so qualified must be in a given sequence, either temporally, spatially, in ranking, in priority or in any other manner.

In the claims below and the description herein, any one of the terms “comprising”, “comprised of” or “which comprises” or the like are, unless clearly expressed otherwise, all open terms that mean “including at least the elements/features that follow, but not excluding others”. Thus, the term “comprising”, and like terms, if used in the claims, should not be interpreted as being limitative to the means or elements or steps listed thereafter. For example, the scope of the expression “a device comprising A and B” should not be limited to devices consisting only of elements A and B. Any one of the terms “including” or “which includes” or “that includes” or the like as used herein are also, unless clearly expressed otherwise, open terms that also mean “including at least the elements/features that follow the term, but not excluding others”. Thus, the term “including” is synonymous with and means “comprising”.

As used herein, the term “exemplary” is used in the sense of providing examples, as opposed to indicating quality. That is, an “exemplary embodiment” is an embodiment provided as an example, as opposed to necessarily being an embodiment of exemplary quality. The term “for example”, or the like, is used similarly in this specification.

The term “carbon-based”, when used in this specification in relation to an electrode of an SMD EDLC device, is intended as a broad term to describe one or more particular components of the electrode. Those components can include one or more of: carbon particles, such as one or a combination of activated carbon particles or carbon black particles (whether amorphous or otherwise) or carbide-derived carbon particles; graphene; carbon nanotubes; carbon fibres; foamed carbon; carbon aerogel; and the like. The components can also include a mixture of types and/or grades of such carbon-based materials. By way of example, a component of carbon particles may include a predetermined combination of similar types of components such as high surface area carbon particles (activated carbon) and high conductivity carbon particles (carbon black). By way of a further example, a component of carbon particles may include a predetermined combination of different types of components such as high surface area carbon particles (activated carbon) and carbon nanotubes. In some embodiments the carbon-based electrodes include non-carbon-based components. For example, in an embodiment the electrodes include a binder for providing cohesion between the carbon particles (and any other particles) in the electrodes. It will also be appreciated that, in other embodiments, binder-less electrodes are used.

One important characterisation for a SMD EDLC device is its DC capacitance I in Farads. This capacitance is measured by drawing a constant current (I_{D}) from a fully charged EDLC device and measuring the time taken (T_{D}) to discharge from a first DC voltage (V₁) to a second voltage (V₂). The DC capacitance C for the given EDLC device is then calculated according to the following formula:

$$C = \frac{{I}_{D} \cdot {T}_{D}}{( {V}_{1} - {V}_{2} )}$$

For like manufactured SMD EDLC devices there will be a variation between devices of the measured DC capacitance. Typically acceptable manufacturing tolerances for DC capacitance are ±20% from the rated capacitance value for the devices, although tighter tolerances are required for some production runs. In further production runs, an acceptable tolerance is ±30% from the rated capacitance value for the devices.

Another important characterisation for a SMD EDLC device is its equivalent series resistance (ESR) in Ohms. The ESR of a given EDLC device can be estimated as the real impedance of the device measured at 1 KHz using the AC current method.

In this specification use is made of the term “liquid” in describing one or more of an element, a compound, a material or other substance. Unless clearly indicated otherwise, the term “liquid” in this specification is intended to indicate that the element, compound, material or substance being described has a state that falls between the freezing point and the boiling point for that respective element, compound, material or substance.

Any numerical range recited in this specification is intended to include all sub-ranges subsumed therein. For example, a range of “from x to y” or “between x and y” is intended to include all sub-ranges between x and y and also the range end points of x and y.

### BRIEF DESCRIPTION OF THE DRAWINGS

Embodiments of the invention will now be described, by way of example only, with reference to the accompanying drawings in which:

FIG. 1 is a perspective view of a first exemplary EDLC device;

FIG. 2 is a side view of the EDLC device of FIG. 1 mounted to a PCB;

FIG. 3 is a rear view of the EDLC device of FIG. 1;

FIG. 4 is an underside view of the EDLC device of FIG. 1;

FIG. 5 is a plan view of the EDLC device of FIG. 1;

FIG. 6 is an underside perspective view of the EDLC device of FIG. 1 prior to being fitted with a plastics base and having its terminals formed to captively retain the base to the housing;

FIG. 7 is a perspective view of the capacitor element of the EDLC device of FIG. 1 with the radial outer ends of the separator and electrodes being shown in a partially unwound state;

FIG. 8 is a perspective view of one of the terminals of the EDLC device of FIG. 1;

FIG. 9 is a rear view of the terminal of FIG. 8;

FIG. 10 is a perspective view of a sealing element of the EDLC device of FIG. 1 in the form of a rubber lid;

FIG. 11 is an enlarged cross-sectional view illustrating the adjacent edges of a single winding of the electrodes and separator in the element of FIG. 7;

FIG. 12 is a perspective view of a housing for a second exemplary EDLC device;

FIG. 13 is a perspective view of the housing of FIG. 12 aligned with an assembled capacitor element and lid for the second exemplary EDLC device;

FIG. 14 is a perspective view of the assembled capacitor element and lid as received within the housing of FIG. 12;

FIG. 15 is a perspective view of the housing of FIG. 12 following the first forming operation;

FIG. 16 is a perspective view of the housing of FIG. 12 following the second forming operation;

FIG. 17 is an enlarged sectional view taken along section line 17-17 of FIG. 16;

FIG. 18 is a flowchart illustrating a method for manufacturing the SMD EDLC device of FIG. 1;

FIG. 19 is a table of performance characteristics for exemplary embodiments; and

FIG. 20 is a schematic illustration (not to scale) of a thermal profile for a housing of an SMD EDLC.

The above drawings are provided to exemplarily illustrate the features included in the specific embodiments described are not necessarily to scale.

### DETAILED DESCRIPTION

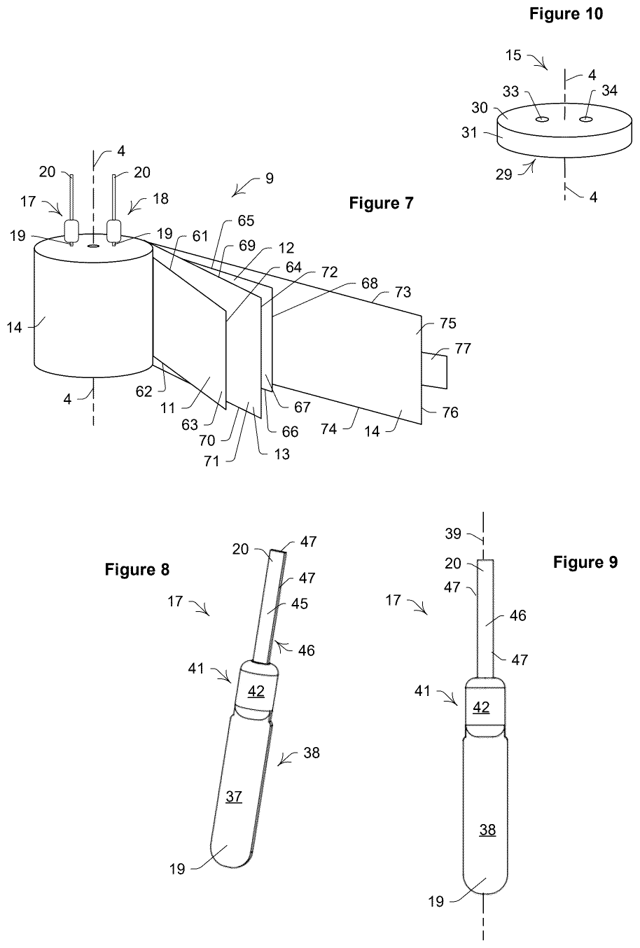

Referring to FIGS. 1 to 7 there is illustrated an electric double layer capacitor (EDLC) device 1 for reflow soldering to a printed circuit board (PCB) 2. Device 1 includes a substantially cylindrical thin-walled malleable aluminium housing 3 that extends along a housing axis 4 between an open end 5 and a closed end 6. Housing 3 has a high thermal conductivity and defines, as best shown in FIG. 6, a substantially circular opening 7 adjacent to end 5 and a substantially cylindrical cavity 8 that extends away from the opening and along axis 4 and which terminates at end 6. A substantially cylindrical capacitor element 9, which is illustrated in FIG. 7, is received complementarily in cavity 8 and includes two elongate, porous and double-sided high surface area carbon-based electrodes 11 and 12. A separator, in the form of two elongate paper-based separator sheets 13 and 14, as best shown in FIG. 6, are alternated, and spiral wound together with electrodes 11 and 12. Sheets 13 and 14 maintain electrodes 11 and 12 in a spaced apart and opposed configuration. An electrolyte impregnates the porous electrodes 11 and 12 as well as sheets 13 and 14 and is contained within cavity 6 for allowing ionic conduction between electrodes 11 and 12. The electrolyte has at 1 atm a freezing point of less than 0° C. and a boiling point of more than 200° C. and will be described in further detail below. A sealing element, in the form of a unitary substantially cylindrical butyl rubber lid 15, extends over and seals opening 7. Illustrated in more detail in FIGS. 8 and 9 is one of the two highly electrically conductive like metal terminals 17 and 18. In use, terminals 17 and 18 each extend between a first end 19 disposed in cavity 8 and a second end 20 disposed externally to cavity 8. Ends 19 are electrically connected to the respective electrodes 11 and 12 and, as best shown in FIG. 6, terminals 17 and 18 extend through opening 7 such that second ends 20 are available for electrical connection to PCB 2.

In this embodiment, element 9 is pre-assembled before being disposed in cavity 8 and is spiral wound along a winding axis. This winding axis is also a notional axis for the substantially cylindrical element 9. Once element 9 is received within cavity 8 the winding axis is substantially aligned with axis 4. Similarly, the substantially cylindrical lid 15 includes an axis that, in the assembled device 1, is also substantively aligned with the housing axis. Accordingly, for the exemplary embodiments described in this specification, the housing axis, the winding axis, the notional axis for element 9 and the axis for lid 15, are considered the same in the finally assembled EDLC device and are all labelled in the drawings with the reference numeral 4. However, it will be appreciated that these different axes are functionally separate, and it is only once the relevant EDLC device is assembled that all the axes effectively directly correspond.

In absence of a clear indication to the contrary, the term “substantially”, when used in this specification to modify a qualitative characteristic of an object, indicates that in essence the characteristic is so, and any departure from the ideal for the characteristic is non-material in terms of the practical performance of the object. Turning by way of example to element 9, which is described above as being “substantially cylindrical”, this indicates that element 9 may not provide: an exact cylindrical outer sidewall due to the spiral wound nature of element 9; and two entirely flat circular ends due to varying axial length, and degree of overlap, of the spiral wound components included within element 9. However, for practical applications in SMT devices, element 9 is able to be regarded as cylindrical. Furthermore, in absence of a clear indication to the contrary, the term “substantially”, when used in this specification to modify a quantitative characteristic of an object, indicates that in essence the characteristic is so, and any departure from the quantity specified is ±5%, ±4%, ±3%, ±2%, and ±1%.

While one or more of the embodiments are described with reference to one or a combination of particularised manufacturing steps, it will be appreciated by the skilled addressee that non-SMT cylindrical EDLC devices are known, and the manufacture of such devices is known. When determining the specific manufacturing steps for an embodiment, the skilled person can select, as is best suited to the specific embodiment: known manufacturing steps other than those described in this specification; or combinations of manufacturing steps, in the same or different order, instead of or in addition to those described in this specification.

In other embodiments the separator includes a single sheet that is folded back across itself to define the two sheets which are integrally connected along the fold. One of the electrodes is placed between the two sheets while the other electrode is placed against the outside of one of the sheets. The resultant stack is then spiral wound together to define the substantially cylindrical capacitor element 9. In further embodiments, the two sheets are not like, and one includes, by way of example, an axial width which is greater than the axial width of the other. By way of a further example, in an embodiment one of the sheets is longer than the other normal to axis 4 and, when spiral wound, extends further circumferentially to define a radial outer surface of element 9.

Device 1 has a rated voltage of 3 Volts, a capacitance of 3.4 Farads and an ESR of 83 mQ. Other embodiments provide for different combinations of rated voltage, capacitance and ESR.

Housing 3 includes a substantially cylindrical thin-walled malleable sidewall 25 that extends between ends 5 and 6 and a substantially planar and circular thin-walled sidewall 26 that extends across end 6 and which is integrally formed with sidewall 25. Although housing 3 is formed initially with sidewall 25 being substantially axially uniform, during the manufacture and assembly of device 1, sidewall 25 is subject to two separate forming operations that vary the shape for sidewall 25 from the initial regular cylindrical form. The first of these forming operations occurs following an insertion of the assembled combination of element 9 and lid 15 into cavity 8, with element 9 being adjacent to end 6 and lid 15 being adjacent to end 5. The first forming operation involves the progressive plastic deformation of sidewall 25 to include a substantially uniform and continuous circumferential concave channel 27 which is adjacent to end 5 and which extends radially inwardly into the axial gap between element 9 and lid 15. Channel 27 defines within cavity 8 a complementarily convex formation that defines, in part, a sealing surface for lid 15 within housing 3. The form and function of this sealing surface is described in more detail below with reference to another exemplary embodiment of the invention.

In further embodiments, element 9 includes more than two electrodes and the separator sheets for maintaining the required physical separation between all the electrodes. For example, in some embodiments four electrodes are spiral wound together in element 9, two of which are electrically connected with terminal 17 to define a composite electrode 11 and the other two of which are electrically connected with terminal 18 to define a composite electrode 12. In other exemplary embodiments, device 1 includes two further terminals for allowing separate external electrical connection to each of the four electrodes. It will be appreciated by those skilled in the art that more than four electrodes are able to be included within element 9.

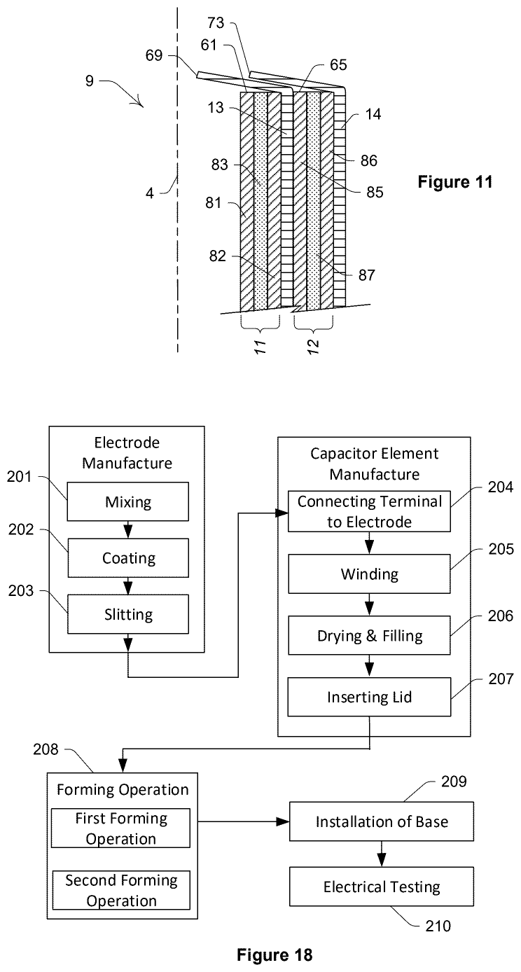

As best shown in FIG. 10, lid 15 includes an inner substantially circular face 29 and an outer substantially circular face 30 and a substantially cylindrical and circumferentially continuous outer sidewall 31 that extends between faces 29 and 30. Lid 15 also includes two spaced apart like apertures 33 and 34 that extend between faces 29 and 30 and which receive in an interference fit, and sealingly engage with, respective terminals 17 and 18 intermediate ends 19 and 20. Lid 15 defines a compression seal with the terminals 17 and 18 that has a sealing path which, in this embodiment, is substantially equal to the axial distance between faces 29 and 30. In the resting state as shown in FIG. 10, the distance between faces 2 and 30 is 3 mm. However, when lid 15 is installed in housing 3, face 31 is substantially uniformly compressed about its circumference radially inwardly, which has the effect of increasing the axial dimension of lid 15 and, hence, the sealing path length between faces 29 and 30. In other embodiments, lid 15 has different dimensions and provides a different sealing path length.

In further embodiments, element 9 is initially received within cavity 8 without lid 15. Following the first forming operation, lid 15 is then axially progressed such that ends 20 of terminals 17 and 18 are received by and extend through respective apertures 33 and 34 and lid 15 is received in cavity 8.

Following from the first forming operation, and with lid 15 disposed within cavity 8, the outer radial periphery of face 29 abuts with the convex formation within cavity 8 that has been defined by channel 27. This partially assembled device 1 is then subjected to the second forming operation, which progressively plastically deforms end 5 of sidewall 25 to define a retaining formation for lid 15. More particularly, the retaining formation in this embodiment is a continuous circumferential flange 28 that extends radially inwardly at end 5 of housing 3. During the formation of flange 28, it is pressed into biased engagement with the radially periphery of face 30. Lid 15 is resiliently deformed and biased into sealing engagement flange 28. Moreover, lid 15 is clampingly engaged to housing 3 between flange 28 and the convex formation within cavity 8 that is defined by channel 27. Sidewall 31 of lid 15 is also sealingly abutted against an inner surface of sidewall 25 that extends between flange 28 and the convex formation within cavity 8 that is defined by channel 27. Accordingly, housing 3 defines a sealing surface against which lid 15 is abutted to affect a compression seal. This compression seal includes a sealing path that is longer than the axial distance between faces 29 and 30.

While the first forming operation and the second forming operation are described as two discrete operations, it will be appreciated by those skilled in the art they these may be performed at a single forming station and in rapid succession. In some embodiments the forming operations are contemporaneous (in that the operations overlap chronologically) while in further embodiments the forming operations are undertaken substantially simultaneously.

The focus of the above description goes to the nature of the forming operations. It will be appreciated that there are a number of steps in addition to and intermediate the first operation and the second operation which have been omitted for the sake of clarity in expressing the details of the above forming operations.

As best shown in FIGS. 8 and 9, end 19 of terminal 17 includes two opposite relatively large surface area faces 37 and 38. End 19 of terminal 17 is formed from aluminium, while end 20 is formed from copper and includes a tin coating to facilitate the creation of a good electrical contact with the relevant contact pad on PCB 2 during and following from the reflow process. In other embodiments, different coatings, such as gold, are used. In further embodiments, ends 19 and 20 are formed from different electrically conductive materials.

In use, the relatively large surface area face 37 of terminal 17 is abutted with electrode 11 to define a commensurately large electrical contact patch with the electrode. End 19 is then fixedly connected both physically and electrically to that electrode prior to the spiral winding of the electrodes 11 and 12 with sheets 13 and 14. In the present embodiment, the fixing of terminal 17 to electrode 11 is done by machine by way of riveting, wire stitching, or the like. As will be described in more detail below, electrodes 11 and 12 include a porous carbon-based layer and an aluminium current collector. In this embodiment, each terminal is attached such that electrical contact is affected directly between the terminal and the current collector of the respective electrode.

Once the spiral winding has occurred, face 38 of terminal 17 is abutted with separator sheet 13 and electrically insulated from the adjacent electrode 12. Terminal 17 includes an axis of symmetry 39 which is, immediately following the spiral winding of electrodes 11 and 12 and sheets 13 and 14, parallel with and radially offset from axis 4. Terminals 17 and 18 are fixedly connected with respective electrodes 11 and 12 such that, following the spiral winding of the electrodes and the separator sheets, the terminals are substantially diametrically opposed and the respective axes 39 are substantially radially equidistant from axis 4. In an embodiment, the relative radial location of the terminals is other than set out above. For example, in an embodiment, the terminals are offset from axis 4 by differing distances. Furthermore, in another embodiment, the terminals are circumferentially offset by other than 180°.

Terminal 17 includes, intermediate its ends 19 and 20, a mounting formation in the form of a ferrule 41 that is integrally formed with end 19. The ferrule includes a substantially cylindrical outer face 42 for defining a continuous sealing surface and a cavity (not shown) for receiving and fixedly engaging physically and electrically with end 20. Once end 20 is received within the cavity, a physically and electrically fixed engagement between ferrule 41 and end 20 is affected by inserting a dose of a fixing compound into the cavity. The fixing compound is some embodiments is a conductive epoxy, while in other embodiments use is made of different fixing compounds such as solder, or the like. In further embodiments, ends 19 and 20 are fixedly connected by ultrasonic welding.

In some embodiments, face 42 of ferrule 41 is non-cylindrical to create a longer sealing path with lid 15. For example, in an embodiment, face 42 is contoured with circumferentially and/or radially extending grooves or other formations to provide a serpentine sealing path with lid 15. That is, once terminals 17 and 18 are received within respective apertures 33 and 34, lid 15 automatically resiliently deforms in and around the grooves or other formations to sealingly engage with face 42 and to define a sealing path that is longer than the axial distance between faces 29 and 30.

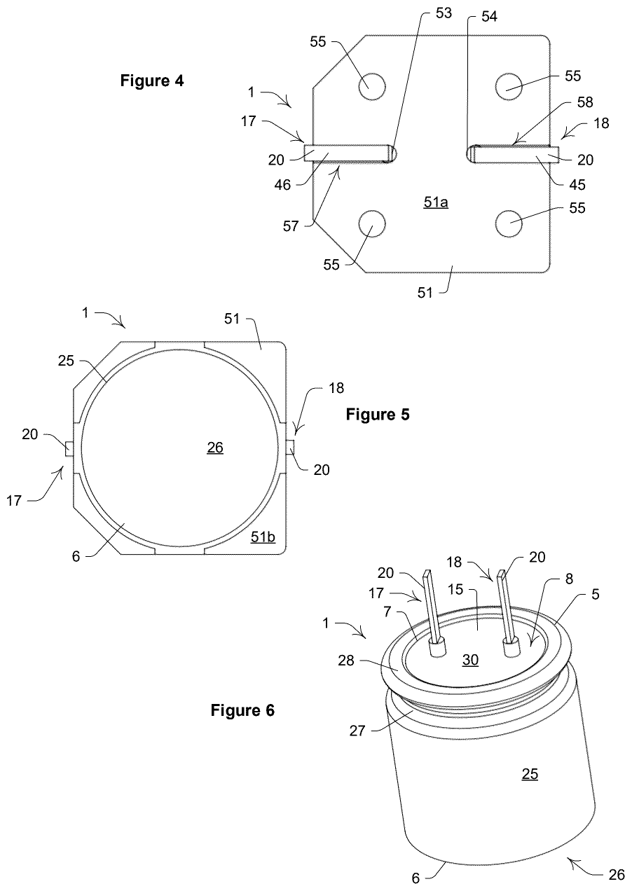

End 20 of terminal 17 includes two opposite relatively large surface area faces 45 and 46 that are joined by relatively narrow faces 47. Applying a force normal to faces 45 and 46 allows for ease of plastic deformation of end 20 from a first position shown illustratively in FIGS. 6, 8 and 9 to a second position shown illustratively in FIGS. 1 to 5 (with particular reference being made to FIG. 4).

While only terminal 17 has been explicitly described above, it will be appreciated that terminal 18 is a like terminal and shares the same structural and functional characteristics.

Device 1 includes an electrically non-conductive rigid high temperature polymer plastics base 51 that is shaped for facilitating machine handling and placement of device 1 on PCB 2. Base 51 also functions to maintain ends 20 of terminals 17 and 18 substantially normal to axis 4 and, in use, substantially parallel with the adjacent face of PCB 2. This facilitates the use of device 1 in a reflow process as it is configured for machine handling and placement on PCB 2 such that ends 20 are parallel with and overlie the respective generally horizontally extending electrical pads on PCB 2 to which terminals 17 and 18 are to be physically and electrically connected.

Base 51 is unitarily formed and includes two circular and spaced apart through apertures 53 and 54 for receiving ends 20 of respective terminals 17 and 18 when end 5 of housing 3 is presented into engagement with the base. On its underside, base 51 includes four projecting spaced apart mounting formations 55 for, in use, abutting with an adjacent surface of PCB 2.

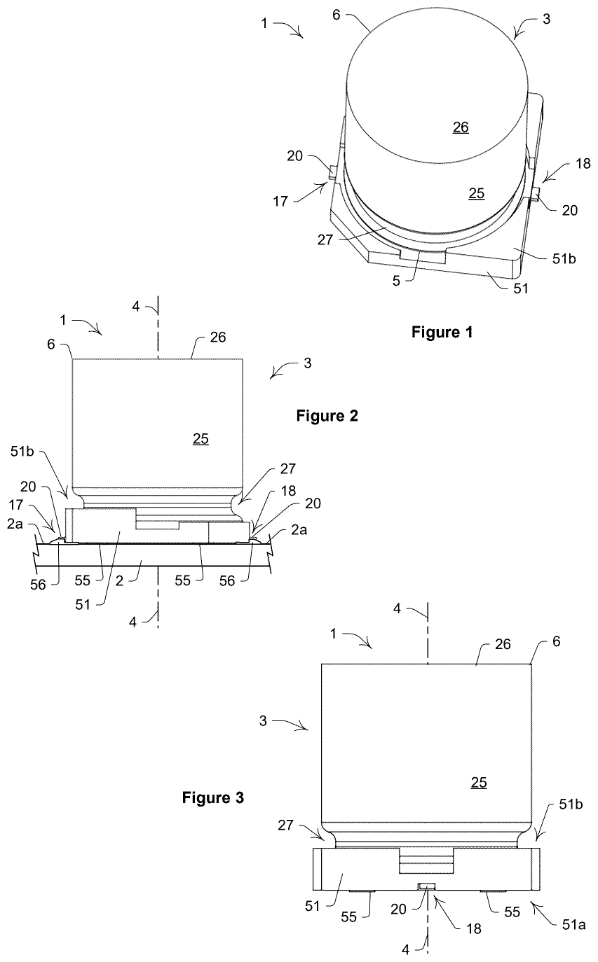

It will be noted by contrasting, for example, FIG. 4 and FIG. 6, that after terminals 17 and 18 are received in apertures 53 and 54, ends 20 of the terminals are plastically deformed normally to faces 45 and 46 such that ends 20 extend substantially normally to both ends 19 and axis 39 to captively retain base 51 in engagement with end 5. Moreover, the deformation of ends 20 of terminals 17 and 18 is such that those ends extend away from each other along a common line and faces 46 and 45 are respectively available to be presented for abutment with two correspondingly spaced apart electrical pads 56 on PCB 2. (See, in particular, FIG. 2). Those pads extend along an upper surface 2a of PCB 2 and each provide a relatively large upper facing surface area that is available for contact with ends 20 of respective terminals 17 and 18. In use, faces 45 and 46 of ends 20 extend substantially parallel with the adjacent upper surface 2a of PCB 2 and the exposed upper surfaces of respective pads 56. The relatively large and exposed upper surface of pads 56 accommodates a tolerance for the machine placement of device 1 on PCB 2 and contributes to the establishment of a good electrical and physical connection between ends 20 and the respective pads once PCB 2 and device 1 are collectively passed through a reflow oven.

It will be appreciated that PCB 2 is able to be single-sided, double-sided, single layered, multilayered, or otherwise, depending upon its design. The PCB 2 will also include a predetermined arrangement of tracks, pads, vias, and other formations for providing the required conducting paths and connection points for the required electronic components to be mounted to the PCB. While in this specification reference is made to PCB 2 having two pads 56, that is done to simplify the disclosure of the embodiments and not to suggest that PCB 2 need only have two pads.

As best shown in FIG. 3, base 51 has a first face 51a (a lower face, in use) for opposing surface 2a and a second face 51b (an upper face, in use) opposite face 51a. Opening 7, in use, is opposed with face 51b.

It will also be noted, particularly from FIG. 4, that base 51 includes two continuous linear channels 57 and 58 along which extend ends 20 of the respective terminals 17 and 18. Channel 57 extends from aperture 53 in a first direction and terminates at a first side of base 51, while channel 58 extends from aperture 54 in a second direction opposite to the first direction and terminates at a second side of base 51 which is opposite to the first side. Ends 20 are partially nested within respective channels 57 and 58 and extend beyond the respective sides of base 51. In other embodiments, channels 57 and 58 are omitted. In an embodiment, either or both of channels 57 and 58 extend through base 51 to define respective elongate open-ended apertures.

In an embodiment, ends 20 extend in the same direction, although remaining spaced apart. In an embodiment, ends 20 extend away from each other but not along a common line. In other embodiments, ends 20 extend away from each other normally.

In an embodiment, the function of apertures 53 and 54 is performed by a single larger aperture. In an embodiment, base 51 includes conductive portions (not shown) in the form of conductive pads that, in use, define extensions of respective ends 20. In an embodiment, the conductive portions extend partially along face 51a and, in use, adjacent to ends 20. In an embodiment, the conductive portions extend along respective channels 57 and 58. The conductive portions provide terminals 17 and 18—and, more particularly, ends 20—with a greater surface area for the solder to affect the required electrical and physical connection with PCB 2.

Base 51 is electrically non-conductive and able to withstand the thermal shock imparted during a reflow process without experiencing any significant physical distortion or other structural deterioration. In this embodiment, base 51 is made substantially from polyphthalamide (PPA). In other embodiments, use is made of other materials, or combination of materials, including one or more of polyether ether ketone (PEEK), liquid crystal polymer (LCP), and similar materials that are stable at temperatures of greater than 200° C.

Reference is made specifically to FIG. 7, where it is shown that electrode 11, in the unwound state, is substantially rectangular and elongate normal to axis 4. Electrode 11 includes two substantially parallel elongate edges 61 and 62 that are spaced apart along axis 4. Electrode 11 includes a radially outer end 63 having an axially extending edge 64 that is normal to and joins with both edges 61 and 62. Similarly, electrode 12, in the unwound state, is substantially rectangular and elongate normal to axis 4. Electrode 12 includes two substantially parallel elongate edges 65 and 66 that are spaced apart along axis 4 substantially the same as edges 61 and 62. Moreover, when spiral wound to form element 9, edges 61 and 62 are adjacent to and overlie respective edges 65 and 66. Electrode 12 includes a radially outer end 67 having an axially extending edge 68 that is normal to and joins with both edges 65 and 66. In the spiral wound configuration, edges 64 and 68 are coterminous, in that in the outmost spiral of the electrodes in element 9, edges 64 and 68 substantially circumferentially overlie each other.

Sheet 13 in the unwound state is substantially rectangular and elongate and includes two substantially parallel elongate edges 69 and 70 that are spaced apart along axis 4 by more than the axial spacing between edges 61 and 62 and, hence, by more than the axial spacing between edges 65 and 66. Moreover, edge 69 extends axially beyond both edges 61 and 65 and edge 70 extends axially beyond, in the opposite direction to edge 69, edges 62 and 66. Sheet 13 includes a radially outer end 71 having an axially extending edge 72 that extends normally to and joins with both edges 69 and 70. When spiral wound to form element 9, edge 72 extends circumferentially beyond edges 64 and 68. Similarly, sheet 14 in the unwound state is substantially rectangular and elongate and includes two elongate edges 73 and 74 that are spaced apart along axis 4 to respectively overlie edges 69 and 70. Sheet 14 includes a radially outer end 75 having an axially extending edge 76 that is normal to and joins with both edges 73 and 74. In the spiral wound configuration, edge 74 extends circumferentially beyond end 72 and is secured to itself with an adhesive strip 77. In some embodiments, edge 76 extends beyond edge 72 by more than one winding of sheet 14 about element 9, and in some embodiments by multiple windings of sheet 14. The additional windings of sheet 14 at the radial outer of element 9 is to provide one or more of: increased frictional engagement at the periphery of element 9 and, hence additional structural integrity to element 9; and increased electrical isolation of the edges of the electrodes from unintended contact with sidewall 26 or other electrically conductive elements.

Further detail of the elongate edges of a single winding of the spiral wound element 9 is illustrated in FIG. 11. More specifically with reference to that Figure, electrode 11 includes a first carbon-based layer 81 with a thickness of 20 microns, a second carbon-based layer 82 with a thickness of 20 microns and an intermediate aluminium sheet current collector 83 with a thickness of 20 microns to which carbon-based layers 81 and 82 are mounted and electrically connected. Similarly, electrode 12 includes a third carbon-based layer 85 with a thickness of 20 microns, a fourth carbon-based layer 86 with a thickness of 20 microns and an intermediate aluminium sheet current collector 87 with a thickness of 20 microns to which layers 85 and 86 are mounted and electrically connected. It will be noted by those skilled in the art that edges 61 and 65 substantially overlie axially and that ends 69 and 73 lie axially outwardly of edges 61 and 65. Moreover, during the spiral winding operation to form element 9, the components being wound into a spiral are maintained under tension to ensure a close and secure fit and to contribute to the structural integrity of the ultimately formed element. For some separator sheet materials during the spiral winding operation this tension, in combination with the material properties of the sheet, results in the axially outer edges deforming radially inwardly toward axis 4 providing a partial or total overlap of edges 61 and 65 by sheets 13 and 14 respectively. In FIG. 11 a total overlap is illustrated. For other separator sheet materials or for lower applied tension the deformation may not occur automatically. In such embodiments, use is able to be made of angled rollers or guides in the winding operation to mechanically induce the deformation or other deflection of sheets 13 and 14.

It will be appreciated by the skilled addressee that, although FIG. 11 illustrates only edges 69 and 70 of separator sheets 13 and 14, a corresponding effect is implemented with edges 70 and 74. Moreover, although only a single winding of element 9 is illustrated in FIG. 11, it will be appreciated that the other windings of sheets 13 and 14 in element 9 are able to be similarly formed.

In other embodiments, the carbon layers have a thickness of other than 20 microns. Typical thickness ranges for such electrodes are in the range of about 10 microns to 200 microns although thicknesses outside this range are able to be used.

The separator sheets used in the above embodiment are made from non-woven fibres and, more particularly, include respective sheets both containing cellulose fibres. The sheets 13 and 14 each have a thickness of about 30 microns. For the selected separator sheets this thickness has been found to be a suitable for a spiral wound device in which there is tension applied in the winding together of the electrodes and separator sheets. As the separator sheets are very porous, if made too thin they will be susceptible to allowing short-circuit connections between the electrodes which will render the EDLC device defective. In other embodiments, where less tension is used in winding the capacitor element, or where a higher manufacturing failure rate can be tolerated, then use is able to be made of a thinner separator.

In some embodiments, the paper-based sheets 13 and 14 include a polymer to provide, during and following from the reflow process, either or both of: additional puncture resistance to the sheets; and additional mechanical integrity to element 9 when undergoing thermal expansion. This is particularly advantageously applied to those embodiments where the selected electrolyte would tend to soften or otherwise weaken a paper only sheet during the elevated temperatures of the reflow process.

In other embodiments, sheets 13 and 14 are made from a different material or combination of materials. Moreover, in an embodiment, sheets 13 and 14 are made from different materials or different combinations of materials from each other. For example, in an embodiment, sheet 14, which extends circumferentially about the outer radial periphery of element 9, is thicker than sheet 13 to provide additional uniformly applied mechanical strength about that outer periphery.

In an embodiment, sheets 13 and 14 are made predominantly from PTFE. Typically, such sheets are able to be thinner than paper-based sheets and are relatively puncture resistance even when stretched during the winding of element 9. Preferentially, such sheets include a surface treatment to increase wettability with the electrolyte.

In other embodiments, different thicknesses are used for the separator sheets. In an exemplary embodiment the paper-based sheets have a thickness of between 20 to 30 microns. In an embodiment, the sheets have a thickness of 30 to 40 microns. In an embodiment, the sheets have a thickness of 40 to 50 microns. In still further embodiments, the sheets have different thicknesses.

In the above embodiment, sheets 13 and 14 are formed substantially from non-woven cellulose fibres. However, in other embodiments, sheets 13 and 14 are formed substantially from other fibres or non-fibrous materials. Examples of such materials include polytetrafluoroethylene (PTFE), polyacrylonitrile (PAN) fibres, aramid fibres, and glass fibres. These materials are able to be surface treated to include one or more layers to provide additional or enhanced properties. For example, for those embodiments making use of polytetrafluoroethylene sheets 13 and 14, those sheets are preferentially surface treated to reduce the reactivity of those sheets with the electrolyte and to improve wettability.

In this embodiment, housing 3 is formed substantially entirely from an aluminium alloy and sidewall 25 has a substantially uniform wall thickness of about 300 microns. In other embodiments, use is made of a wall thickness greater than 300 microns, including greater than 350 microns, greater than 370 microns, greater than 380 microns, greater than 390 microns and greater than 400 microns. In further embodiments, use is made of a wall thickness less than 300 microns, including less than 290 microns, less than 280 microns, less than 270 microns, less than 260 microns and less than 250 microns. The wall thickness is selected to provide sufficient mechanical strength for device 1, having regard to the anticipated internal pressures within cavity 8 during the reflow process and the anticipated mechanical shocks that need to be withstood during the subsequent operation of device 1. Regard is also had to minimising the amount of material required to construct housing 3. A further consideration in selecting the sidewall thickness is to provide the required ability for sidewall 25 to be plastically deformed to define both the sealing formation and the retention formation for the sealing element. In an embodiment, housing 3 and sidewall 25 are formed from stainless steel.

In the above-described embodiment, sidewall 25 of housing 3 extends 12.6 mm axially between ends 5 and 6 and has an external diameter of 12.5 mm. Prior to being subjected to the two forming operations, sidewall 25 of housing 3 extends 13.5 mm axially between ends 5 and 6.

Sidewall 26 has a wall thickness of 370 microns. Moreover, sidewall 26 includes one or more venting formations (not shown) which are integrally formed channels for preferentially rupturing should the internal pressure within cavity 8 exceed a predetermined threshold. In this embodiment, the venting formations are two normally intersecting channels that extend radially in sidewall 26. These channels result in sidewall 26 rupturing once the pressure on that sidewall reaches 20 to 30 kgcm⁻². The reduced wall thickness of sidewall 26 adjacent to the channels is about 70 microns. In other embodiments, different venting configurations, or different configurations of venting formations, are used. Moreover, where different rupturing pressures are desired, use is made of deeper or shallower channels.

In further embodiments, sidewall 26 has a different sidewall thickness. Moreover, in additional embodiments, sidewall 26 is other than substantially planer and includes either a convex outer facing surface for providing additional structural strength to housing 3 or, alternatively, a concave outer facing surface for providing predetermined deformational characteristics for housing 3 when under load.

It will be appreciated that, when device 1 is mounted to PCB 2, sidewalls 25 and 26 are exposed to the surrounding atmospheric conditions both during the reflow process and during the subsequent operating lifetime of device 1. Moreover, thin-walled sidewalls 25 and 26 are formed from substantially only aluminium alloy which has a thermal conductivity of more than 100 Wm⁻¹K⁻¹ at room temperature. Accordingly, for a given reflow process, the internal components within cavity 8 (and, in particular, capacitor element 9) will experience a maximum temperature that is higher than would be the case for prior art EDLC devices having thermally insulating packaging and/or housings. Conversely, following from the reflow process, device 1 will reach the environmental temperature more quicky than the prior art device. Given this, the internal components for device 1 are selected in combination not for continuous high temperature performance but, rather, to adequately withstand a once-off thermal shock during the reflow process (whether that include a single pass or multiple passes through the reflow oven) while still providing a predetermined operating lifetime at a maximum operating temperature that is much lower than the maximum temperature experienced during the reflow process. The thermal shock experienced during the reflow process by the internal components within device 1, while potentially involving a higher maximum temperature than would typically be the case for prior art SMD EDLC devices, should remain at that maximum for a shorter duration.

In an embodiment, sidewall 25 is formed from a material which has a thermal conductivity between 50 to 100 Wm⁻¹K⁻¹ at room temperature. In an embodiment, sidewall 25 is formed from a material which has a thermal conductivity between 100 to 150 Wm⁻¹K⁻¹ at room temperature. In an embodiment, sidewall 25 is formed from a material which has a thermal conductivity between 150 to 200 Wm⁻¹K⁻¹ at room temperature. In an embodiment, sidewall 25 is formed from a material which has a thermal conductivity between 200 to 250 Wm⁻¹K⁻¹ at room temperature.

In other embodiments use is made of a housing of a different size to complementarily accommodate electrodes of commensurate size.

Electrode 11 for device 1 extends 7 mm axially between edges 61 and 62 and electrode 12 also extends 7 mm axially between edges 65 and 66. Sheet 13 extends 8 mm axially between edges 69 and 70 and sheet 14 also extends 8 mm axially between edges 73 and 74. Electrodes 11 and 12 are axially centred with each other and with sheets 13 and 14. As mentioned above, device 1 provides a capacitance of approximately 3.4 Farads and an equivalent series resistance (ESR) of approximately 83 mQ. In other embodiments different capacitances and ESR values are obtainable by using different electrode dimensions, different electrode materials (having different surface areas), different thicknesses of the electrodes and separator sheets, and different lengths of electrodes and separator sheets. Where the dimensions of electrodes 11 and 12 and sheets 13 and 14 change from that used in the current embodiment, or the number of windings of those components to form element 9 changes from that used in the current embodiment, there may be a need to use a housing having different dimensions to housing 3.

The exterior of sidewalls 25 and 26 are pre-coated with a thin lacquer layer that is cured to provide an electrically insulating barrier. An additional pre-assembly step for the present embodiment is adhering a paper liner having a thickness of 30 microns on the interior surface of sidewall 26. This is performed to reduce the risk of any inadvertent electrical contact being established between sidewall 26 and the electrodes 11 and 12 included in element 9. In this embodiment, use is made of a paper sheet that is of the same material as sheet 13.

In this embodiment layers 81, 82, 85 and 86 are substantially identical and include like constituents. In particular, each of the layers includes a predetermined homogenous mixture of high surface area activated carbon particles, high conductivity carbon black particles and a binder. The binder contributes to: cohesion between the carbon particles in the same layer; and adhesion of each carbon-based layer to the adjacent current collector.

The activated carbon particles in this embodiment are selected to have more than 50% of the pore volume with a pore size of greater than 2 nm to better combine with electrolytes having a higher viscosity than more conventional electrolytes which make use of organic liquids such as acetonitrile. These activated carbon particles are referred to as mesoporous active carbon particles. It has been found that the use of such mesoporous carbon particles in the embodiments not only improves the electrical performance of an EDLC device having a relatively viscous electrolyte, but it also facilitates manufacture of the EDLC device as the carbon particles are easier to wet with the electrolyte and, hence, contribute to more predictability in the manufacturing process.

It will be appreciated that the pore size for the carbon particles referred to in the preceding paragraph is distinct from the porosity of layers 81, 82, 85 and 86 themselves. More particularly, device 1 makes use of porous electrodes each containing a mixture of active particles. The active particles in this embodiment are activated carbon particles having pores, and conductive particles in the form of carbon black particles. While all the active materials contribute to a high surface area between the electrodes and the adjacent electrolyte, this is particularly so for the activated carbon particles. The electrolyte permeates into the porous electrodes and into the pores of the activated carbon particles. A Helmholtz double layer is formed not just with the exterior carbon particles contained within the electrode, but with the sub-surface carbon particles within that electrode. This permeation or wetting of the electrode by the electrolyte contributes to the higher volumetric capacitances that are obtained by EDLC devices relative to conventional electrolytic capacitors. To achieve the highest capacitance in an EDLC device for a given volume, use is often made of microporous activated carbon particles as these usually offer the highest surface area per unit volume of the particles. The inventors have discovered that, for those embodiments making use of more viscous electrolytes, it can be advantageous for an electrode to include mesoporous activated carbon particles instead of or in addition to microporous carbon particles. These mesoporous carbon particles typically provide a smaller surface area per volume than microporous carbon particles and, hence, reduce the capacitance provided by the electrode. However, the larger pores of the mesoporous particles have been found to reduce the ionic resistance for the electrolyte and, consequently, improve the performance of the EDLC device primarily by contributing to a lower ESR for the device. This effect is particularly evident with electrolytes having a higher viscosity.

A mesoporous particle is a particle having more than 50% of its pore volume with a pore size of greater than 2 μm. While in the above embodiment the mesoporous carbon particles are activated carbon particles, in other embodiments use is made of other mesoporous materials. In an exemplary embodiment, the mesoporous carbon particles are contained in a carbon foam.

In an embodiment, the electrolyte has a viscosity at room temperature that is greater than the viscosity of water at room temperature. In an embodiment, the viscosity of the electrolyte at room temperature is more than double the viscosity of water at room temperature. In an embodiment, the viscosity of the electrolyte at room temperature is more than three times the viscosity of water at room temperature. In an embodiment, the viscosity of the electrolyte at room temperature is more than four times the viscosity of water at room temperature. In embodiments, the viscosity of the electrolyte at room temperature is respectively between: two to two and a half times the viscosity of water at room temperature; two and a half times to three times the viscosity of water at room temperature; three to three and a half times the viscosity of water at room temperature; and three and a half times to four times the viscosity of water at room temperature. In an embodiment, the viscosity of the electrolyte at room temperature is less than ten times the viscosity of water at room temperature.

The binder in this specific embodiment includes carboxymethylcellulose (CMC). However, in other embodiments, other binders are used which do not significantly degrade at 200° C. or more. In an embodiment, the binder includes instead, or in addition, one or more of: a salt of CMC (such a sodium carboxymethyl cellulose); polytetrafluoroethylene (PTFE); a salt of polystyrene sulfonate (PSS), such as a Group I or Group II metal salt of PSS, including magnesium polystyrene sulfonate (MgPSS), sodium polystyrene sulfonate (NaPSS), lithium polystyrene sulfonate (LiPSS), and calcium polystyrene sulfonate (CaPSS); polyvinylidene fluoride (PVDF); and a polyimide. These binders have been found to be relatively stable at the elevated temperatures such as those encountered by the binders in the reflow process. While such binders may soften during the reflow process, the use of a cylindrical spiral wound element 9 operates to maintain more uniform pressure across the entire surface of the electrodes and thereby better allows the shape and configuration of layers 81, 82, 85 and 86 to be maintained. In further embodiments, the binder is omitted for either or both of adhesion and/or cohesion when the material selection for the electrodes is such that sufficient structural integrity is able to be achieved without the use of that binder. For example, this can occur in some embodiments in which the electrodes include a predetermined combination of carbon nanotubes and carbon particles. The use of a spiral wound element 9 has been found to well accommodate the use of binder-less electrodes as any potential structural weakness resulting from the omission of the binder is at least in part mitigated by the structural benefit gained by the construction of element 9. In other embodiments use is made of different binder-less electrodes. Examples of further binder-less electrodes for EDLC devices include vertically aligned carbon nanotubes directly grown on current collectors, entangled carbon nanotubes, and entangled carbon nanotubes with other high surface area carbon materials such as activated carbon particles or graphene materials.

The electrolyte within housing 3 is comprised of a neutral organic compound, such as a polar aprotic solvent, that includes an organosulfur sulfone compound such as sulfolane and an organic salt that includes a tetrafluoroborate salt of a quaternary ammonium cation, such as tetramethylammonium, tetraethylammonium, tetrapropylammonium, tetrabutylammonium, 2-(methylthio)ethylammonium, spiro-bis-pyrrolidinium (SBP), N,N-dimethylpyrrolidinium, N-methyl-N′-propylpyrrolidinium, N,N′-dimethylimidazolium, N-methyl-N′-ethylimidazolium, or N-methyl-N′-propylimidazolium. The salt is present in a sufficiently high concentration such that the freezing point of the electrolyte is depressed to less than or equal to 0° C. at 1 atm.

In other embodiments, the neutral organic compound or solvent, such as polar aprotic solvent, includes a carbonate ester (such propylene carbonate (PC)), or a cyclic lactone (such as gamma-butyrolactone (GBL)). These neutral organic compounds/solvents are combined with an organic salt to enable the ionic conduction in the electrolyte. Once such organic salt includes a tetrafluoroborate anion. In an embodiment, the salt is present in a sufficiently high concentration such that the boiling point of the resultant electrolyte is elevated to greater than or equal to 200° C. at 1 atm. In an embodiment, salt is present in a sufficiently high concentration such that the boiling point of the resultant electrolyte is elevated to greater than or equal to 210° C. at 1 atm. In further embodiments, the salt is present in a concentration such that the boiling point of the resultant electrolyte is, or is elevated to, greater than or equal to 220° C. at 1 atm. In exemplary embodiments, the salt is present in a concentration such that the boiling point of the resultant electrolyte is, or is elevated to, greater than or equal to 230° C. at 1 atm. In still further embodiments, the salt is present in a concentration such that the boiling point of the resultant electrolyte is, or is elevated to, greater than or equal to 240° C. at 1 atm.

In an embodiment, the electrolyte includes a mix of neutral organic compounds, such as a mix of two or different neutral organic solvents, such as two or more different polar aprotic solvents. In one embodiment, the electrolyte comprises two or more carbonate esters. In an exemplary embodiment, the electrolyte includes a mixture of sulfones, such as a mixture of a linear sulfone and a cyclic sulfone. In another exemplary embodiment the electrolyte includes a mixture of two cyclic sulfones. In another exemplary embodiment, the electrolyte includes a mixture of carbonate esters, such as a mixture of a linear carbonate ester and cyclic carbonate ester. In another exemplary embodiment, the electrolyte includes a mixture of cyclic carbonate esters.

In further embodiments the electrolyte comprises an ionic liquid. In still further embodiments, the electrolyte includes a predetermined combination of an ionic liquid and a neutral organic compound or solvent. Exemplary neutral organic compounds or solvents include one, or a combination of at least two, of sulfolane, PC and GBL.

The selection of the electrolyte for the current embodiment was based upon a combination of factors such as the electrolyte having one or more of the following characteristics:
(a) a boiling point of greater than or equal to 200° C. at 1 atm, which reduces the pressure increase in the housing during the reflow process;
(b) a relatively high ionic mobility for the operating temperature range selected for device 1;
(c) good temperature stability during the thermal shock experienced during the reflow process;
(d) low reactivity with the selected electrodes over the operating temperature range and during the thermal shock experienced during the reflow process, having particular regard to the electrolyte's potential reactivity with the carbon-based layers and, more particularly, with any binder included in those layers or any impurities typically found in the carbon particles;
(e) low reactivity with the selected separator over the operating temperature range and during the thermal shock experienced during the reflow process;
(f) low transmission rates arising from electrolyte vapour permeating through lid 15 over the required operating temperature range and during the thermal shock experienced during the reflow process; and
(g) low leakage from cavity 8 due to progressing along sealing path over the required operating temperature range and during the thermal shock experienced during the reflow process.

It has been found that for an SMD EDLC device of the above embodiment, which is subject to a reflow process, it is preferred to select the electrolyte from those that are a liquid between at least 0° C. and 200° C. at 1 atm. It will be appreciated that in some embodiments, the electrolyte may comprise organic solvents and/or organic salts having a stated freezing point which is higher than 0° C. This occurs when such organic solvents and/or organic salts, in situ, effectively have their freezing point suppressed. For example, in an embodiment, the in situ freezing point of the electrolyte is suppressed to below 0° C. due to either or both of: the concentration of the dissolved organic salt; and the high surface area of the activated carbon.

In preferred embodiments, the binder does not dissolve substantively when mixed in a sample of the electrolyte that is heated to 200° C. at 1 atm. In some embodiments electrodes 11 and 12 do not include a binder, which can allow a broader range of electrolytes to be used in the SMD EDLC device as consideration need not be had to the reactivity of the binder with the electrolyte at the elevated temperatures encountered during the reflow process.

As will be understood by those skilled in the art, the electrolyte provides the SMD EDLC device with a source of charged ions that migrate to the surfaces of the respective electrodes to form the pair of Helmholtz layers in the device. Moreover, it will be appreciated that the use of a highly thermally conductive housing for a SMD EDLC device, such as occurs in the embodiments described herein, results in the electrolyte and other internal components of the EDLC device reaching a maximum temperature during the reflow process of about 200° C. to 240° C., even if only for a short time. Accordingly, the electrolyte is selected for device 1 to withstand this temperature profile while still providing the required lifetime performance. Some embodiments are designed for a reflow process which results in the electrolyte being exposed to a higher maximum temperature than 240° C.

It will be noted that device 1 is a single cell device. The voltage able to be maintained across this single cell during normal use over the planned lifetime is referred to as a cell voltage. Accordingly, the rated voltage for device 1, which is a single cell device, is the same as the cell voltage for device 1. The electrolytes used in device 1 and the other embodiments described in this specification are organic electrolytes which allow for cell voltages above 2 Volts.

In other embodiments, use is made of a plurality of such cells connected:
(a) in parallel-typically to reduce overall ESR of the resultant device or increase overall capacitance of the resultant device relative to a single cell device; and/or
(b) in series-typically to increase the operational voltage of the resultant device relative to a single cell device.

It will be appreciated by those skilled in the art that EDLC devices making use of aqueous-type electrolytes have cell voltages of less than 2 Volts. By way of contrast, the EDLC devices of the embodiments, which make use of organic electrolytes, typically provide cell voltages in the range of 2.3 to 4 Volts. The maximum operating voltage for a SMD EDLC device is often determined by the required performance of the device over a predetermined operating lifetime and operating conditions as those devices with higher cell voltages often experience accelerated aging characteristics.

The electrolytes used in the embodiments described in this specification are selected in part for not generating excessive pressure in housing 3 when device 1 is subjected to reflow oven temperatures. This reduces the risk, during the reflow process, of the electrolyte leaking from the housing because of: undue stressing and weakening of the seal; and bursting and failure of the housing. The electrolyte of an embodiment is selected to have a vapour pressure which is less than 1 atm (1.013 bar or 101.3 Kpa) at 200° C. In other embodiments, respective electrolytes have a vapour pressure which is less than 1 atm at: 210° C.; 220° C.; 230° C.; 240° C.; 250° C.; and 260° C.

The electrolyte in an embodiment is also selected to be chemically stable for the reflow oven temperatures that are to be experienced by the device. Moreover, the electrolyte is selected such that, at the relevant reflow oven temperatures, it does not substantively dissolve, degrade, or be incorporated into, other components of the EDLC device such as any binder, the separator, the current collector, any carbons used in the electrodes, the housing, and the lid (or other sealing element).

When assessing whether an electrolyte does not substantively dissolve, degrade, or be incorporated into, other components of the EDLC device, regard is had in an embodiment to electrical testing performed before and after the device has undergone the reflow process.

As will be understood by those skilled in the art, the change in ESR is usually an increase and the change in capacitance usually a decrease. For some devices the ESR decreases and/or the capacitance increases following from the reflow process.

In an embodiment the electrolyte comprises an organic salt which is, or a mixture of two or more organic salts which are, a liquid at room temperature. Such an organic salt is commonly referred to as an ionic liquid. Alternatively, or additionally, the electrolyte comprises an organic salt which is a solid salt in isolation at room temperature, and which is mixed with a neutral organic compound or solvent. This mixture provides, in part or in full, an electrolyte which is an ionically conducting liquid in the temperature range required by the reflow process that is to be used to connect the SMD EDLC device to PCB 2 and the operating temperature range for the SMD ELDC device once so mounted. The neutral organic compound or solvent used in an embodiment may be liquid solid. However, where use is made of an organic solid, the organic solid is preferably heated and mixed with an organic salt, an organic liquid or an organic salt that is a liquid (ionic liquid), to form a eutectic-type mixture in which the melting point of the mixture is much lower than the melting point of the organic solid or the organic salt/organic liquid. In some embodiments, the organic liquid or liquids may be added, while in further embodiments organic salt or salts may be added to form the eutectic-type mixture. The eutectic-type mixture of the embodiments results in a liquid electrolyte at room temperature and typically also at lower temperatures. In an embodiment, the eutectic-type mixture has a freezing point of less than 0° C. In an embodiment, the eutectic-type mixture has a freezing point of less than −10° C. In an embodiment, the eutectic-type mixture has a freezing point of less than −20° C.

The organic salt comprises a cation and anion. In those embodiments where the salt is a liquid at room temperature—that is, where the salt is an ionic liquid—that salt is able to be used without mixing with a neutral organic compound or solvent, although it could be. If the organic salt is a solid at room temperature it is mixed with a neutral organic compound or solvent, such as a polar aprotic solvent, which is either a solid or a liquid at room temperature. The organic compound or solvent enables or enhances the dissociation of the ions of the salt.

In an embodiment, the ionic liquid comprises a mixture of two or more salts—that is, two or more different ionic liquids may be mixed or combined.

As noted above, the salt component of the electrolyte is made up of a cation and an anion. For organic electrolytes in EDLC devices it is preferred there is only a weak interaction between the anion and the cation so that the salt easily dissociates into the cation and anion. For an embodiment, the selection of the salt also has regard to the salt being sufficiently stable: at the required cell voltage or voltages for the EDLC device; for the reflow oven temperature profile to which the EDLC device will be subjected; and over the planned operating lifetime of the device at a given maximum operating temperature.

Example cations which have been found sufficiently stable for use in the embodiments are quaternary ammonium salts. More specifically, such exemplary cations have the following chemical structure:

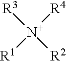

where R¹, R², R³ and R⁴ are alkyl substituents. In an embodiment, R¹, R², R³ and R⁴ are each, independently, straight chained or branched C₁-C₇ alkyl groups. In an embodiment, R¹, R², R³ and R⁴ are each, independently, straight chained or branched C₁-C₄ alkyl groups. In an embodiment, R¹, R², R³ and R⁴ are each, independently, straight chained or branched C₁-C₂ alkyl groups, and such salts may be dissolved in an organic solvent in use. In an embodiment, R¹ is different to at least one of R², R³ and R⁴. In an embodiment, R¹, R², R³ and R⁴ are different to each other.

In other embodiments, the quaternary ammonium cation comprises disubstituted pyrrolidinium with the following chemical structure:

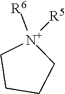

where R⁵ and R⁶ are each alkyl substituents. In an embodiment, R⁵ and R⁶ are each, independently, straight chained or branched C₁-C₇ alkyl groups. In an embodiment, R⁵ is different to R⁶.

In further embodiments, the quaternary ammonium cation comprises a spiro-bicyclic compound where the common atom in the spiro structure is nitrogen. An exemplary chemical structure for such a cation is as follows:

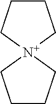

This structure represents spiro-bispyrrolidinium cation (SBP) where two five membered rings are connected through a common nitrogen atom. In other embodiments use is made of similar spiro-configured cations but where one five-membered ring is joined to a six-membered ring. In additional embodiments, two six-membered rings are joined in a spiro-configuration through a common nitrogen.

In further embodiments, the cation comprises a heterocyclic nitrogen containing cation. An example of the chemical structure of such a cation is as follows:

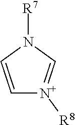

This structure includes an imidazolium ring with substituents R⁷ and R⁸ on both the nitrogen atoms in the heterocycle. In various embodiments, R⁷ and R⁸ are each, independently, straight chained or branched C₁-C₇ alkyl groups.

In an embodiment, the anion is a borate and/or a phosphate and, more specifically, tetrafluoroborate (TFB) and/or hexafluorophosphate (HFP). Other embodiments made use of alternative and/or additional anions from different borate compounds such as tetracyanoborate, fluorotricyanoborate, difluorodicyanoborate, trifluorocyanoborate, bis(oxalato) borate, difluoro (oxalato) borate.

In further embodiments, the anion is a sulfonylimide and, more specifically, one or more of bis(fluorosulfonyl)imide (FSI) and bis(trifluoromethylsulfonyl)imide (TFSI).

It will be appreciated that TFSI and EMI-TFB form an electrolyte that is an ionic liquid. Those embodiments making use of such ionic liquids need not include an organic solvent. However, in other embodiments, the ionic liquid or liquids are combined with one or more organic solvents to improve the conductivity and other selected characteristics of the resultant electrolyte.

Further embodiments make use of alternative or additional organic salts such as SBP-TFB and/or SBP-TFSI. These salts, in isolation, are solids at room temperature and are in some embodiments pre-mixed with one or more of organic solvents, in either solid or liquid form, to provide the required liquid electrolyte.

For those embodiments making use of one or more neutral organic compounds/solvents-whether in the liquid and/or solid form—the selection of that or those compounds/solvents has regard to the temperature profile of the reflow process and the anticipated maximum temperature to which the electrolyte will be exposed. In practice, the relevant embodiments make use of neutral organic compounds/solvents having a relatively high boiling point. It will be appreciated, given the benefit of the teaching herein, that the boiling point of the neutral organic compound does not necessarily need to be higher than 250° C., or even higher than 200° C. Rather, the inventors have discovered the more significant factor is for the ultimately formed electrolyte to have a sufficiently high boiling point when measured at 1 atm. For example, in some embodiments, use is made of electrolytes with very high cation and anion concentrations to provide a significant decrease the vapour pressure of the electrolytes relative to low concentration mixtures. This provides a significant increase in the temperature at which the vapour pressure of the electrolyte will be 1 atm.

In some embodiments preferential regard is had to organic solvents, such as polar aprotic solvents, having a high dielectric constant to facilitate, in use, both dissolution and/or mixing of the salt and to maximise the dissociation of the salt. In preferred embodiments, the solvent is a polar aprotic solvent.

Exemplary embodiments make use of a neutral organic compound or solvent comprising one or more linear or cyclic carbonate esters. In an embodiment, the neutral organic compound comprising one or more linear carbonate esters. For example, in an embodiment, the linear carbonate ester is diethyl carbonate.

In an embodiment, the neutral organic compound comprises one or more cyclic carbonate esters. These cyclic carbonate esters are high dielectric liquids with high boiling points and include, by way of example, those carbonate esters with the following chemical structure:

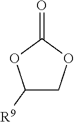

The five-membered ring carbonate includes R⁹ which is H, a methyl group, a fluorinated methyl, or F. In other embodiments, the neutral organic compound includes those in which there is further substitution with fluorine on the carbon atoms of the cyclic structure, i.e., the cyclic carbonate ester includes at least one C—F bond.

In further embodiments, the neutral organic compound is a lactone. For example, in some embodiments, the neutral organic compound is a liquid such as gamma-butyrolactone (GBL) which has the following chemical structure:

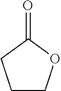

It is noted that GBL is less viscous than many of the carbonate ester liquids and is able to be selected for those embodiments where the SMD EDLC device requires a higher ionic conductivity for the electrolyte.

In still further embodiments, the neutral organic compound comprises a linear or cyclic sulfone, which has a relatively high boiling point. By way of example, there is provided the following chemical structure for a linear sulfone:

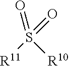

The substituents R¹⁰ and R¹¹ are each independently, a C₁-C₄ alkyl group. In some embodiments R¹⁰ and R¹¹ are the same alkyl groups, while in other embodiments R¹⁰ and R¹¹ are different alkyl groups. In an exemplary embodiment, R¹⁰ and R¹¹ are both ethyl groups and the organic liquid is diethylsulfone (DES).

By way of a further example, in additional embodiments the neutral organic compound comprises a cyclic sulfone such as that having the following chemical structure:

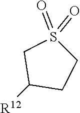

In this structure, R¹² is either H (in that the neutral organic compound is sulfolane) or a methyl group (in that the neutral organic compound is 3-methylsulfolane).

The neutral organic compounds described above have been found applicable to embodiments of SMD EDLC devices due to having relatively high boiling points and being generally very stable electrochemically.

In other embodiments the neutral organic compound includes one or more nitrile or dinitrile liquids or organic solids with high boiling points and relatively high dielectric constants. By way of example, these include the compounds having the following chemical structures:

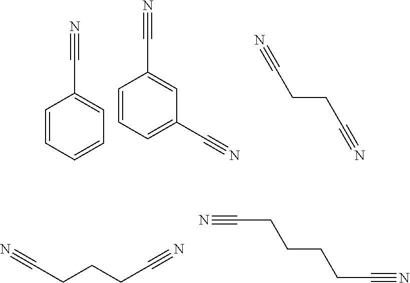

While some embodiments make use of an electrolyte comprising a single organic salt, in other embodiments the electrolyte includes a mixture of two or more organic salts. Similarly, while there are embodiments making use of an electrolyte comprising a single neutral organic compound/solvent, in other embodiments the electrolyte includes a mixture of two or more neutral organic compounds/solvents.

In exemplary embodiments the percentage by weight of the salt in the electrolyte is between 10% and 100%. The higher end of this range is primarily directed to those embodiments using organic salts which are ionic liquids and where no further organic liquid solvent is used in combination with the ionic liquid. For other embodiments, the percentage by weight of the salt in the electrolyte is between 20% and 100%. In further embodiments, the percentage by weight of the salt in the electrolyte is between: 30% and 100%; 40% and 100%; or 50% and 100%.

Due to the relatively small size of SMD EDLC devices, and the considerable design constraints concerning the footprint and overall volume of the device, it becomes even more important to optimise the volume and configuration of the components used in the device to provide the required electrical properties. For example, enabling the use of a thin-walled housing contributes to the resultant EDLC device having more available volume for components that directly contribute to a greater capacitance and/or lower ESR. By avoiding the prior art need for a bulky housing to provide thermal protection, the embodiments are able to provide good electrical characteristics per unit volume and are able to be manufactured with less costly materials and less complex manufacturing steps.

The axial thickness of lid 15 is 3 mm, which has been found to provide, in the context of the reflow process: sufficient sealing length for the selected electrolyte; sufficient thickness to contain the rate of electrolyte vapour transmission through the lid; and sufficient resistance to breaking the compression seal due to gaseous build-up in the cavity during the reflow process and over the normal operational lifetime of the device. In other embodiments, to provide an additional safety factor, or to better accommodate other electrolyte/separator/electrode combinations, use is made of one or more of: an axially thinner lid or an axially thicker lid; a structurally reinforced lid; and a lid constructed of a different material or materials. For example, in specific other embodiments, lid 15 makes use of an alternative synthetic rubber such as ethylene propylene diene monomer (EPDM) rubber. Moreover, in further embodiments, lid 15 is a composite lid and includes more than one material. For example, in one embodiment, lid 15 includes a central portion of rigid electrically insulating plastics in which apertures 33 and 34 are formed, and a continuous circumferential outer radial portion of synthetic rubber. In another embodiment, lid 15 includes a reinforcing element that is encased in rubber so its centre further resists deflecting axially outwardly due to any gaseous pressure build-up in cavity 8 during the reflow process and over the operational lifetime of the device.

As device 1 includes a compression seal, lid 15 is able to include other deformable and compressible materials to affect the seal. The material is also selected, similarly to the other materials mentioned above, on the basis that it can withstand the reflow oven temperatures and that it has a sufficient inertness with the electrolyte in particular so as to not substantially impact upon the operating lifetime of the device.

In some embodiments lid 15 includes an internal or external barrier element for inhibiting the flow of electrolyte vapour through lid 15. In one such embodiment, the barrier element is a PTFE layer applied to either or both of faces 29 and 30. In another such embodiment, the barrier element is a dopant within the rubber, or a dopant in a layer of the rubber. In a further such embodiment, the barrier element is separate from but adjacent to lid 15.

When selecting the material or materials for lid 15 regard is had not only to the anticipated thickness to provide the required barrier properties and sealing properties, but also to any constituents in the materials that may interact with the electrolyte or other components of device 1. In selecting any dopants or additives for the rubber particular regard is had to those dopants or additives being inert, or at least sufficiently inert over the intended temperature range and lifetime of the device, when exposed to the electrolyte.

It will be appreciated by those skilled in the art that the thin-walled aluminium housing 3 provides very little thermal mass or thermal protection for device 1 and that the compression seal of opening 7 is not typically a hermetic seal. Accordingly, the electrolyte and other components used within device 1 are selected to ensure, in combination, both: the EDLC device adequately withstands the reflow process notwithstanding the high thermal conductivity of housing 3; and a sufficiently low rate of electrolyte loss from cavity 8 through the compression seal. Once that selection is made, the use of thin-walled aluminium housing 3 and a compression seal are advantageous as they are able to contribute to one or more of:
(a) a decrease in the complexity and cost of manufacturing relative to manufacturing techniques for known SMD EDLC devices;
(b) a decrease relative to known SMD EDLC devices in the volume occupied by materials having the primary purpose of providing thermal mass or thermal protection.
(c) for a given footprint/volume on PCB 2, a greater volume is available for internal components within device 1 that contribute to higher capacitance and/or lower ESR; and
(d) a decrease in the use of expensive materials having the primary purpose of providing thermal mass or thermal protection.

It will be appreciated by those skilled in the art, given the benefit of the disclosure herein, that device 1 is relatively small in volume and mass and housing 3 provides little or no thermal shielding for element 9 and the electrolyte. Accordingly, a design assumption for device 1 is that, during the reflow process, all of its components will be exposed to close to the full range of reflow oven temperatures with little delay. Moreover, and conversely, once removed from the reflow oven, device 1 will relatively quickly return to the ambient temperature. These design assumptions are different to those used for conventional SMD EDLC devices and allow for the embodiments to use a thin-walled housing having a high thermal conductivity. This, in turn, simplifies manufacture of the embodiments, reduces the need for bulky and expensive packaging, and lends the design to mass manufacture.

Device 1, while designed for use in a reflow process, has an operating temperature range of −20° C. to 70° C. In other embodiments, the operating temperature range is −20° C. to 80° C., while in further embodiments the operating temperature range is from −10° C. to 70° C. In still further embodiments, the operating temperature range is from −40° C. to 70° C. or from −20° C. to 85° C. In any event, device 1 is designed for mass manufacture and use, and the operating temperature range has an upper limit which is considerably less than the temperatures experienced during the reflow process and which would be required to be withstood by devices directly applicable to extreme environments. For a planned operating lifetime, device 1 would be expected to undergo a single reflow process but to otherwise remain in its designed operating temperature range. And while device 1 may tolerate exposure to a number of separate reflow processes, such exposure could impact upon the lifetime of the device.

It will be appreciated that a single reflow process may include a single pass through a reflow oven or multiple passes through the reflow oven. If multiple passes are used, this will typically include two passes.

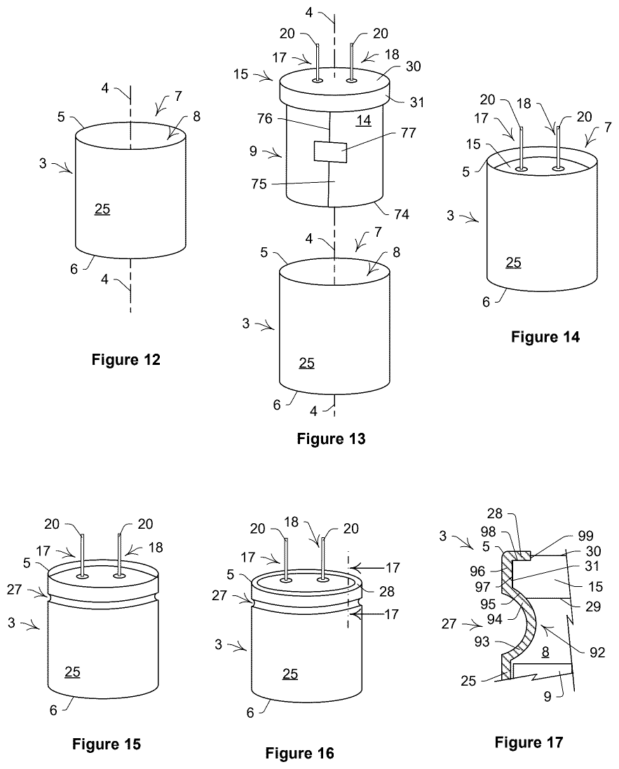

Reference is now made to FIGS. 12 to 17 which illustrate a sequence of steps in the assembly/production of a second exemplary SMD EDLC device 91. In these Figures corresponding features to those for device 1 are denoted by corresponding reference numerals. That does not imply that the corresponding features in device 91 are identical in size, shape, materials, or performance to those in device 1, although they could be. Rather, the correspondence is in the general function of the like-labelled features.

Turning to FIG. 12, a unitarily formed thin-walled aluminium alloy housing 3 is presented to a processing station and maintained in a fixed configuration by a station jig (not shown). Sidewall 25 of housing 3 is substantially uniformly cylindrical along axis 4. FIG. 13 illustrates an assembled combination of element 9 and lid 15 which is loaded to an automated assembly jig (not shown) and presented to the processing station in axial alignment with housing 3. Moreover, edge 74 is disposed adjacent to end 5 and opening 7. In this embodiment element 9 has a maximum external diameter which is about 0.9 mm less than the internal diameter of cavity 8. This allows for an ease of automated insertion of element 9 into housing 3 and space for thermal expansion of element 9 radially within cavity 8 during the subsequent reflow process.

When reference is made to element 9 being complementarily received in cavity 8, that is primarily intended to express that the external curved exterior of element 9 is generally complementary with the adjacent and opposed inner surface of sidewall 25. The external diameter of element 9 will be less than the internal diameter of sidewall 25 to allow for insertion of element 9 into cavity 8. Preferentially, the difference between the two diameters is small. As will be appreciated, given the benefit of the teaching herein, the axial dimensions of sidewall 25 and element 9 differ considerably to accommodate the first and second forming operations and the inclusion of lid 15.

With element 9 complementarily received within cavity 8, and due to the use of thin wall thicknesses, the difference between the outer diameter of element 9 and the outer diameter of sidewall 25 is 1.5 mm. In an embodiment, the difference between the outer diameter of element 9 and the outer diameter of sidewall 25 is between 1.4 mm and 1.5 mm. In an embodiment, the difference between the outer diameter of element 9 and the outer diameter of sidewall 25 is between 1.3 mm and 1.4 mm. In an embodiment, the difference between the outer diameter of element 9 and the outer diameter of sidewall 25 is between 1.5 mm and 1.6 mm. In an embodiment, the difference between the outer diameter of element 9 and the outer diameter of sidewall 25 is between 1.6 mm and 1.7 mm.

Following that automated insertion, the resulting assembly is as shown in FIG. 14. As with device 1, device 91 includes a thin paper liner adhered to the internal surface of sidewall 26. In the configuration shown in FIG. 14, edges 70 and 74 of respective sheets 13 and 14 are closely adjacent to, or abutting with, the paper liner. Moreover, edges 70 and 74 have been deformed radially inwardly toward axis 4 and provide a total overlap of edges 62 and 66 by sheets 13 and 14 respectively. The combination of this total overlap and the inclusion of a paper liner in cavity 8 reduces the risk of an inadvertent short-circuit being created between either of electrodes 11 and 12 and the conductive sidewall 26.

In other embodiments the difference in the diameter of element 9 and the internal diameter of cavity 8 is less than 0.9 mm, and the automated insertion of element 9 into cavity 8 occurs with a greater degree of mechanical precision than is required in the production of device 91.

In this embodiment, lid 15 has a diameter that approximates the interior diameter of cavity 8. During the advancement of the assembled combination of element 9 and lid 15 into cavity 8 there is an increased chance that at least a portion of the radial periphery of face 29 will engage with end 5. Should such engagement occur, the material properties of lid 15 result in the lid resiliently deforming and continuing to advance of the lid into cavity 8 and into the configuration shown in FIG. 14.

The automated assembly jig then releases the combination of element 9 and lid 15 and retracts it from the processing station. Following this, a first forming tool (not shown) is advanced to the processing station to undertake the first forming operation to form channel 27. The resultant assembled combination being illustrated in FIG. 15. In this embodiment, the first forming tool moves radially into progressive engagement with the exterior surface of sidewall 25 while the station jig rotates housing 3 and the contents of cavity 8 about axis 4. In other embodiments, the station jig moves radially and rotationally about axis 4 and the first forming tool remains fixed. In further embodiments other options are used to affect the required relative movement between the station jig and the first forming tool to form channel 27.

The first forming tool is then retracted from the processing station and a second forming tool (not shown) is advanced to the processing station. The second forming tool is progressively advanced to roll end 5 to define flange 28, the result of which is illustrated in FIGS. 16 and 17. In this embodiment, the second forming tool moves radially into progressive engagement with the exterior surface of sidewall 25 adjacent to end 5 while the station jig rotates housing 3 and the contents of cavity 8 about axis 4. In other embodiments, the station jig moves radially and rotationally about axis 4 and the second forming tool remains fixed. In further embodiments other options are used to affect the required relative movement between the station jig and the second forming tool to form flange 28.

Reference is now made more specifically to FIG. 17 where there is illustrated in more detail the shape, configuration and placement of channel 27 and the compression seal that is provided by lid 15. More particularly, channel 27 defines on the interior surface of sidewall 25 a convex protrusion 92 that extends radially inwardly into cavity 8 and circumferentially continuously about housing 3 and in a plane that is normal to axis 4. Protrusion 92 includes a first shoulder portion 93 and a second shoulder portion 94, where portion 94 defines a first interior sealing surface 95 for housing 3. Housing 3 includes a substantially cylindrical engagement portion 96 which extends axially between shoulder portion 94 and the radial outer end of flange 28 for defining a second interior sealing surface 97 for housing 3. Flange 28 defines a third interior sealing surface 98 and an adjacent fourth interior sealing surface 99 for housing 3.

In use, and as shown in FIG. 17, protrusion 92 extends radially inwardly into cavity 8 and is disposed between element 9 and lid 15. In FIG. 17 the axial spacing between element 9 and lid 15 is exaggerated to more clearly demonstrate other features. Shoulder portion 93 limits any post-production axial play of element 9 within cavity 8.

During the formation of flange 28, the radial periphery of lid 15 is clampingly engaged and resiliently deformed to conform with surfaces 95, 97, 98 and 99. This operation creates a continuous compression seal between:
(a) sealing surface 95 and both: the radial outer periphery of face 29; and a portion of face 31;
(b) sealing surface 97 and a further portion of face 31;
(c) sealing surface 98 and the radial outer periphery of face 30; and
(d) sealing surface 99 and a further portion of face 30.

The length of the sealing path provided by the above combination is greater than the axial distance between faces 29 and 30.

The formation of flange 28, in compressing lid 15 about its radial periphery, also has the effect of reducing the diameter of apertures 33 and 34 and, hence, improving the sealing engagement, and interference fit, of lid 15 with terminals 11 and 12. This interference fit facilitates lid 15 resisting axial deflection should any pressure later build in cavity 8 during normal operation due to the generation of gasses within device 1.

In some embodiments, ferrules 41 of terminals 11 and 12 are precoated with a sealing compound to further the sealing engagement and interference fit with lid 15.

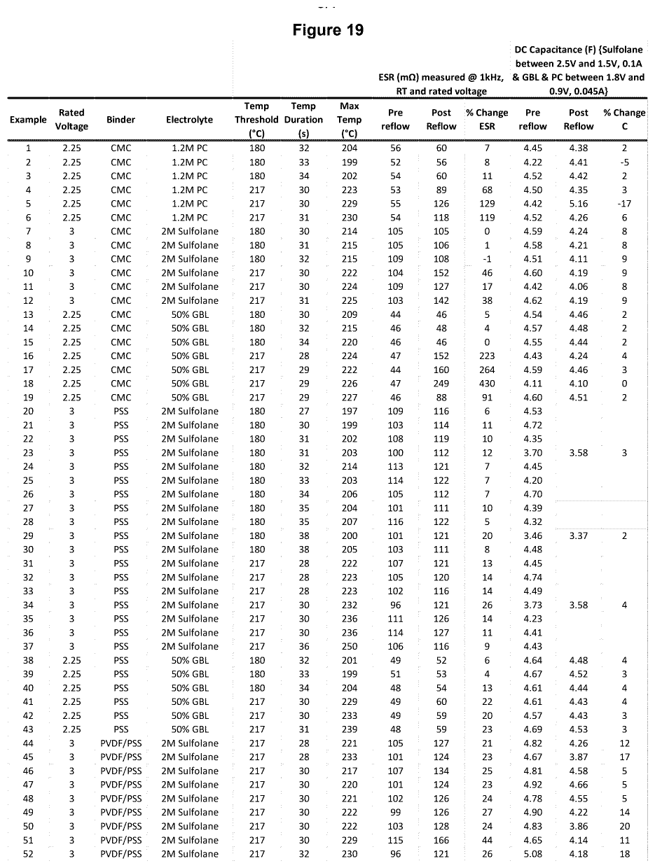

FIG. 19 provides details for fifty-two exemplary embodiments (the Examples). These Examples each include a manually wound capacitor element and the same housing used for device 1 described above. Common characteristics of the Examples include:

| | |
|---|---|
| Carbon-based | Mesoporous activated |
| material | carbon and carbon black |
| Electrode (L × W) | 260 mm × 7 mm |
| Current Collector | 20 μm thick aluminium sheet |
| Electrodes | Double-sided carbon-based layers |
| | (that is, carbon-based material is |
| | coated on each side of the current |
| | collector to define two carbon- |
| | based layers). |
| Separator | 30 μm thick paper separator |
| | (cellulose fibres and PET) |
| Electrolyte Volume | 0.6 mL |
| Base Separator Wetted | 1 drop (approx. 0.06 mL) |
| Drying Conditions | −100 kPa, 140 ° C. (> 8 hrs) |
| (Figure 18, step 206) | |

The carbon-based layers each have a thickness of 50 μm, with the exceptions of: Examples 38 to 43, where there was observed minor variation in the thickness along the electrodes; and Examples 44 to 52, which have carbon-based layers have a thickness of 70 μm.

For the binders referred to in FIG. 19: the term “CMC” refers to carboxy methyl cellulose, sodium salt; the term “PSS70k” refers to polystyrene sulfonate sodium salt (MW=70,000 amu); and the term “PVDF/PSS” refers to a mixture of PVDF and PSS having weight percentages of solids of 67% and 33% respectively. For the PVDF/PSS binder, an exemplary form of PSS is polystyrene sulfonate sodium salt (MW=70,000 amu) and an exemplary commercially available form of PVDF includes that supplied by Solvay Speciality Polymers under the product name Solef® 2042 Latex.

For Examples 1 to 23, 26, 27, 29 to 34 and 37 to 43, the mixture of activated carbon, carbon black and binder is: 100 parts by weight of activated carbon; 40 parts by weight of carbon black; and 15 parts by weight of the binder. For Examples 24, 25, 28, 35 and 36, the mixture of activated carbon, carbon black and binder is: 100 parts by weight of activated carbon; 40 parts by weight of carbon black; and 20 parts by weight of the binder. For Examples 44 to 52, the mixture of activated carbon, carbon black and binder is: 100 parts by weight of activated carbon; 30 parts by weight of carbon black; and 15 parts by weight of the binder.

The electrolytes used in the Examples are further described in the following table.

| Listed Electrolyte | Description |
|---|---|
| 2 M Sulfolane | 2 M SBPBF4 in Sulfolane |
| | dried to less than 20 ppm water |
| 50% GBL | 50% by weight SBPBF4 in gamma- |
| | butyralactone dried to less than 20 ppm water |
| 1.2 M PC | 1.2 M SBPBF4 in propylene |
| | carbonate dried to less than 20 ppm water |

It is expected that the manual assembly of the Examples will contribute to a greater performance variation that would be ultimately achieved in an automated manufacture of such EDLC devices.

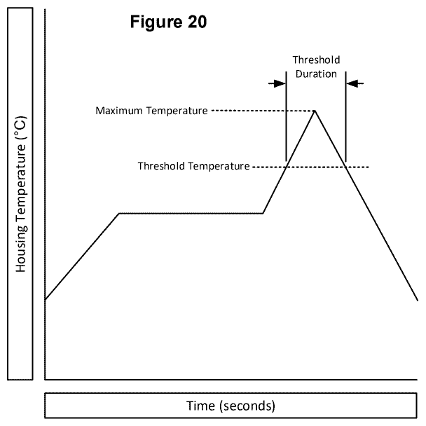

The Examples were individually tested as follows. Firstly, prior to the device being subject to the reflow simulation, the initial ESR or the pre-reflow ESR (which is referred to as ESR₁) and DC the capacitance for the device were measured at room temperature and pressure. A thermocouple was then located against the external cylindrical sidewall of the housing, about midway axially, and held in place with a short strip of adhesive Kapton® tape. The temperature measurement provided by the thermocouple during the simulated reflow process is referred to as the housing temperature (T_{H}) for the device. It will be appreciated that, due to the high thermal conductivity of the housing, T_{H} should be less sensitive to minor variations in the location of the thermocouple on the sidewall. The device was located as a sole component upon a PCB with the device terminals extending parallel to and resting upon respective pads on the PCB. Both the PCB and the device were then placed in a test oven. The test oven was controlled to expose the device and PCB to an oven thermal profile which simulates the thermal profile of a typical reflow oven. This oven thermal profile gave rise to a predetermined thermal profile for the housing temperature, where the latter is schematically illustrated in FIG. 20. For each thermal profile there is specified a temperature threshold (T_{T}) and a temperature duration (t_{D}) for T_{H}. For the Examples, T_{T} was selected to be either 180° C. or 217° C., which represent respectively the two temperatures relevant to the liquidus state of two common solder types. Additionally, tp was selected to be between about 25 to 40 seconds, as representative of the time T_{H} remains above T_{T} during a reflow process to best ensure the solder forms the required physical and electrical connection between the device terminals and the respective pads on the PCB. Also provided in FIG. 19 is the measurement obtained for the maximum housing temperature for each exemplary device during the performance of the simulated reflow process.

Following from the simulated reflow process, the device was allowed to cool and, at room temperature and pressure, a post-test ESR measurement was undertaken to provide a second ESR or a post-reflow ESR (which is referred to as ESR₂) and, for most of the Examples, the DC capacitance for the device. The measured values, where taken, for each exemplary device of ESR₁, ESR₂, and the pre- and post-DC capacitances are set out in FIG. 19 together with the corresponding percentage changes in the values.

It will be appreciated that, during the simulation, the temperature of the surface of the PCB is more usually higher than T_{H} at corresponding times, as the PCB is coated with a thermally absorbent material to aid in heating the solder paste that has been pre-applied to the pads. Moreover, T_{H} lags temporally the oven temperature and, during the usual durations of a predetermined thermal profile, experiences a maximum temperature of less than the maximum oven temperature.

It will be noted from FIG. 19 that, with the exception of Example 9, after T_{H} has followed the predetermined thermal profile,

$${ESR}_{2} \geq {ESR}_{1} , and \frac{100 * ( {ESR}_{2} - {ESR}_{1} )}{{ESR}_{1}} \leq 500.$$

It will be also noted from FIG. 19 that there is at least one example respectively illustrating each of the following conditions being satisfied:

$$\frac{100 * ( {ESR}_{2} - {ESR}_{1} )}{{ESR}_{1}} \leq 300 ; \frac{100 * ( {ESR}_{2} - {ESR}_{1} )}{{ESR}_{1}} \leq 150 ;$$

$$\frac{100 * ( {ESR}_{2} - {ESR}_{1} )}{{ESR}_{1}} \leq 120 ; \frac{100 * ( {ESR}_{2} - {ESR}_{1} )}{{ESR}_{1}} \leq 100 ;$$

$$\frac{100 * ( {ESR}_{2} - {ESR}_{1} )}{{ESR}_{1}} \leq 70 ; \frac{100 * ( {ESR}_{2} - {ESR}_{1} )}{{ESR}_{1}} \leq 50 ;$$

$$\frac{100 * ( {ESR}_{2} - {ESR}_{1} )}{{ESR}_{1}} \leq 40 ; \frac{100 * ( {ESR}_{2} - {ESR}_{1} )}{{ESR}_{1}} \leq 20 ;$$

$$\frac{100 * ( {ESR}_{2} - {ESR}_{1} )}{{ESR}_{1}} \leq 15 ; \frac{100 * ( {ESR}_{2} - {ESR}_{1} )}{{ESR}_{1}} \leq 10 ;$$

$$\frac{100 * ( {ESR}_{2} - {ESR}_{1} )}{{ESR}_{1}} \leq 5 ; \frac{100 * ( {ESR}_{2} - {ESR}_{1} )}{{ESR}_{1}} \leq 2 ; and$$

$$\frac{100 * ( {ESR}_{2} - {ESR}_{1} )}{{ESR}_{1}} \leq 1.$$

It will be also noted from FIG. 19 that where T_{T}=180° C., there is at least one example respectively illustrating each of the following conditions being satisfied:

$$\frac{100 * ( {ESR}_{2} - {ESR}_{1} )}{{ESR}_{1}} \leq 50 ; \frac{100 * ( {ESR}_{2} - {ESR}_{1} )}{{ESR}_{1}} \leq 20 ;$$

$$\frac{100 * ( {ESR}_{2} - {ESR}_{1} )}{{ESR}_{1}} \leq 15 ; \frac{100 * ( {ESR}_{2} - {ESR}_{1} )}{{ESR}_{1}} \leq 10 ;$$

$$\frac{100 * ( {ESR}_{2} - {ESR}_{1} )}{{ESR}_{1}} \leq 5 ; \frac{100 * ( {ESR}_{2} - {ESR}_{1} )}{{ESR}_{1}} \leq 2 ; and$$

$$\frac{100 * ( {ESR}_{2} - {ESR}_{1} )}{{ESR}_{1}} \leq 1.$$

It will be also noted from FIG. 19 that the Examples have a rated voltage of between 2 to 4 Volts.

The Examples of FIG. 19 use electrolytes based upon organic liquids—that is, non-aqueous liquids—to reduce the environmental concerns that can be associated with aqueous electrolytes. However, an embodiment includes a device containing an aqueous electrolyte.

Further details about an exemplary method of manufacturing devices of the embodiments are provided below.

According to an embodiment there is provided an electric double layer capacitor (EDLC) device for reflow soldering to a PCB 2 having a PCB surface 2a with two electrical pads 56, wherein the device includes:
base 51 having a first face 51a for opposing surface 2a and a second face 51b opposite face 51a;
housing 3 for defining: an opening 7 that, in use, is opposed with face 51b; and a cavity 8 that extends away from opening 7;
a substantially cylindrical capacitor element 9 for being received in cavity 8, element 9 including:

two carbon-based electrodes 11 and 12, wherein each electrode includes carbon particles; and
a porous separator in the form of two separator sheets 13 and 14 that are spiral wound together with electrodes 11 and 12, wherein sheets 13 and 14 maintain the electrodes in a spaced apart and opposed configuration and includes one or more of: polytetrafluoroethylene; cellulose fibres;
polyacrylonitrile fibres; aramid fibres; and glass fibres;
an electrolyte within cavity 8 for allowing ionic conduction between electrodes 11 and 12, the electrolyte having at 1 atm a freezing point of 0° C. or less and a boiling point of 200° C. or more;
a sealing element in the form of lid 15 for providing a compression seal for sealing opening 7; and
two terminals 17 and 18, each of which extends between first ends 19 disposed in cavity 8 and second ends 20 disposed externally to cavity 8, wherein: ends 19 are electrically connected to the respective electrodes 11 and 12; and terminals 17 and 18 extend through opening 7 and base 51 such that, in use, ends 20 are substantially parallel with face 2a and electrically connected to respective pads 56.

According to an embodiment of the invention there is provided an SMD EDLC device for reflow soldering to PCB 2 and which includes:
housing 3 for defining opening 7 and cavity 8 that extends away from opening 7;
capacitor element 9 for being received in cavity 8, element 9 including two carbon-based electrodes 11 and 12 and a separator formed from two separator sheets 13 and 14 for maintaining electrodes 11 and 12 in a spaced apart and opposed configuration;
an electrolyte within cavity 8 for allowing ionic conduction between electrodes 11 and 12, the electrolyte having at 1 atm a freezing point of 0° C. or less and a boiling point of 200° C. or more;
a sealing element in the form of lid 15 for providing a compression seal for sealing opening 7; and
two terminals 17 and 18, each of which extends between a first end 19 disposed in cavity 8 and a second end 20 disposed externally to cavity 8, wherein: the ends 19 are electrically connected to the respective electrodes 11 and 12; and terminals 17 and 18 extend through opening 7 such that ends 20 are available for electrical connection to PCB 2.

In other embodiments the electrolyte has at 1 atm a boiling point of: 210° C. or more; 220° C. or more; 230° C. or more; 240° C. or more; 250° C. or more; or 260° C. or more. In further embodiments, the electrolyte has at 1 atm a freezing point of: 10° C. or less; 20° C. or less; 30° C. or less; or 40° C. or less.

According to an embodiment of the invention there is provided an SMD EDLC device for reflow soldering to PCB 2 and which includes:
malleable housing 3 for defining opening 7 and cavity 8 that extends away from opening 7;
capacitor element 9 for being received in cavity 8, element 9 including two carbon-based electrodes 11 and 12, and a separator in the form of two separator sheets 13 and 14 that are spiral wound together with electrodes 11 and 12, wherein sheets 13 and 14 maintain electrodes 11 and 12 in a spaced apart and opposed configuration;
an electrolyte within cavity 8 for allowing ionic conduction between electrodes 11 and 12;
a sealing element in the form of lid 15 for sealing opening 7; and
two terminals 17 and 18, each of which extend between respective first ends 19 for locating within cavity 8 and respective second ends 20 for locating externally to cavity 8, wherein: the ends 19 are electrically connected to respective electrodes 11 and 12; and terminals 17 and 18 extend through opening 7 such that ends 20 are available for electrical connection to PCB 2.

According to an embodiment of the invention there is provided an SMD EDLC device for reflow soldering to PCB 2 and which includes:
housing 3 having a high thermal conductivity for defining opening 7 and cavity 8 that extends away from opening 7;
capacitor element 9 for being received in cavity 8, element 9 including two carbon-based electrodes 11 and 12 and a separator formed from two separator sheets 13 and 14 that are spiral wound together with electrodes 11 and 12, wherein the separator sheets 13 and 14 maintain electrodes 11 and 12 in a spaced apart and opposed configuration;
an electrolyte within cavity 8 for allowing ionic conduction between electrodes 11 and 12;
a sealing element in the form of lid 15 for sealing opening 7; and
two terminals 17 and 18, each of which extend between respective first ends 19 for locating within cavity 8 and respective second ends 20 for locating externally to cavity 8, wherein: the ends 19 are electrically connected to respective electrodes 11 and 12; and terminals 17 and 18 extend through opening 7 such that ends 20 are available for electrical connection to PCB 2.

According to an embodiment of the invention there is provided an SMD EDLC device for reflow soldering to PCB 2 and which includes:
substantially cylindrical housing 3 for defining opening 7 and cavity 8 that extends away from opening 7;
capacitor element 9 for being received in cavity 8, element 9 including two carbon-based electrodes 11 and 12 and a separator formed from two separator sheets 13 and 14 that are spiral wound together with electrodes 11 and 12, wherein sheets 13 and 14 maintain electrodes 11 and 12 in a spaced apart and opposed configuration;
an electrolyte within cavity 8 for allowing ionic conduction between electrodes 11 and 12, the electrolyte having at 1 atm a freezing point of 0° C. or less and a boiling point of 200° C. or more;
a sealing element in the form of lid 15 for sealing opening 7; and
two terminals 17 and 18, each of which extends between a first end 19 disposed in cavity 8 and a second end 20 disposed externally to cavity 8, wherein: ends 19 are electrically connected to respective electrodes 11 and 12; and terminals 17 and 18 extend through opening 7 such that ends 20 are available for electrical connection to PCB 2.

According to an embodiment of the invention there is provided an SMD EDLC device for reflow soldering to PCB 2 and which includes:
housing 3 for defining opening 7 and cavity 8 that extends away from opening 7;
substantially cylindrical capacitor element 9 for being received in cavity 8, element 9 including two electrodes 11 and 12 each containing carbon particles, a binder for providing cohesion between the particles in each electrode and a separator in the form of two separator sheets 13 and 14 that are spiral wound together with electrodes 11 and 12, wherein the separator sheets 13 and 14 maintain electrodes 11 and 12 in a spaced apart and opposed configuration and the binder includes at least one of: carboxymethylcellulose (CMC); a salt of CMC (such a sodium carboxymethyl cellulose); polytetrafluoroethylene (PTFE); a salt of polystyrene sulfonate (PSS), such as a Group I or Group II metal salt of PSS, including magnesium polystyrene sulfonate (MgPSS), sodium polystyrene sulfonate (NaPSS), lithium polystyrene sulfonate (LiPSS), and calcium polystyrene sulfonate (CaPSS); polyvinylidene fluoride (PVDF); and a polyimide;
an electrolyte within cavity 8 for allowing ionic conduction between electrodes 11 and 12;
a sealing element in the form of lid 15 for sealing opening 7; and
two terminals 17 and 18, each of which extends between a first end 19 disposed within cavity 8 and a second end 20 disposed externally to cavity 8, wherein: ends 19 are electrically connected to respective electrodes 11 and 12; and terminals 17 and 18 extend through opening 7 such that ends 20 are available for electrical connection to PCB 2.

According to an embodiment of the invention there is provided an SMD EDLC device for reflow soldering to PCB 2 and which includes:
substantially cylindrical housing 3 for defining opening 7 and cavity 8 that extends away from opening 7;
capacitor element 9 for being received in cavity 8, element 9 including two carbon-based electrodes 11 and 12 and a separator in the form of two separator sheets 13 and 14 that are spiral wound together with electrodes 11 and 12, wherein separator sheets 13 and 13 maintain electrodes 11 and 12 in a spaced apart and opposed configuration;
an electrolyte within cavity 8 for allowing ionic conduction between electrodes 11 and 12;
a sealing element in the form of lid 15 for sealing opening 7; and
two terminals 17 and 18, each of which extend between respective first ends 19 for locating within cavity 8 and respective second ends 20 for locating externally to cavity 8, wherein: ends 19 are electrically connected to respective electrodes 11 and 12; and terminals 17 and 18 extend through opening 7 such that ends 20 are available for electrical connection to PCB 2.

According to an embodiment of the invention there is provided an SMD EDLC device for reflow soldering to PCB 2 and which includes:
malleable housing 3 for defining opening 7, cavity 8 that extends away from opening 7, a sealing surface adjacent to opening 7 and a retention formation in the form of flange 28;
the substantially cylindrical capacitor element 9 for being received in cavity 7, element 9 including two carbon-based electrodes 11 and 12 and a separator in the form of two separator sheets 13 and 14 that are spiral wound together with electrodes 11 and 12, wherein sheets 13 and 14 maintain electrodes 11 and 12 in a spaced apart and opposed configuration;
an electrolyte within cavity 8 for allowing ionic conduction between electrodes 11 and 12;
a sealing element in the form of lid 15 for seating against the sealing surface for sealing opening 7, wherein flange 28 maintains the seating of lid 15; and
two terminals 17 and 18, each of which extends between a first end 19 disposed in cavity 8 and a second end 20 disposed externally to cavity 8, wherein: ends 19 are electrically connected to respective electrodes 11 and 12; and terminals 17 and 18 extend through opening 7 such that ends 20 are available for electrical connection to PCB 2.

It will be appreciated by those skilled in the art that the electrodes of EDLC devices have a much greater surface area than the electrodes of conventional electrolytic capacitors of the same size. Selecting materials for the electrodes to contribute to this greater surface area typically also results in electrodes that are in relative terms more mechanically fragile and/or more susceptible to reacting chemically with other elements in the device. These phenomena become more pronounced with the design of smaller EDLC devices suited to surface mount applications due to: a drive toward the use of thinner layers of materials; and less thermal mass in the overall device to shield the electrolyte and other components from the thermal shock of the reflow process. Moreover, smaller EDLC devices with a lower thermal mass, when subjected to the reflow process, undergo a more rapid change in temperature than for a larger non-SMD EDLC device. The more rapid thermal expansion of the individual components within the SMD EDLC device, and the different rates of expansion for different components, creates greater structural and chemical strains within the device. It has been appreciated by the inventors that accommodating this increased rate of temperature change, without having to resort to bulky packaging and expensive manufacturing techniques, contributes to the overall advantages of those embodiments. Factors of the embodiments which contribute to better performance include: an electrolyte which has a low reactivity with the other materials in and of the housing for the temperatures and temperature profile of the reflow process; a spiral wound cylindrical capacitor element; a complementary cavity for the capacitor element; a thin-walled housing which provides not only a high level of mechanical support to the capacitor element during the reflow process, but substantially uniform mechanical support to the capacitor element as it is subjected to thermal expansion during the reflow process. In particular, it has been found that thermal expansion of the spiral wound capacitor element is more pronounced radially than axially. While not wishing to be bound by theory, it is understood that, as the radial expansion occurs, the action of the tensioned winding of the components in the relatively small spiral wound capacitor element results in that expansion being substantially equal in all radial directions. This reduction in any point loading it understood to reduce the risk of localised deformation or damage being induced in the electrodes or separator sheets. Moreover, as element 9 expands radially its outer radial surface progresses into engagement with the interior surface of sidewall 25. Should that expansion continue and the outer radial surface of element 9 move into full or close to full engagement with sidewall 25, then that sidewall is shaped to both withstand any anticipated radial forces while retaining the shape of element 9. For example, should element 9 initially be slightly misaligned with axis 4, during any subsequent thermal expansion it will, due to the shape and configuration of the interior of sidewall 25, be brought into alignment.

While not wishing to be bound by theory, it is understood that the high surface area materials used in the electrodes for EDLC devices, and particularly the materials used in carbon-based electrodes, can be difficult to thoroughly decontaminate of impurities prior to or during the manufacture of the electrode and the EDLC devices. This results in an increased susceptibility of such devices for reactivity between any chemical functionalities within those impurities and the ions in the electrolyte. This effect is typically exacerbated at higher operating voltages and higher temperatures such as those encountered during a reflow process as the production of unwanted gases within the housing is increased. Conventional SMD EDLC devices have attempted to counter this reactivity with a prismatic housing having one or more of the following characteristics: hermetic sealing to best prevent ingress of unwanted materials that would give rise to additional gassing; structurally stronger housings to withstand the greater internal pressures resulting from the increased gassing; and increased thermal mass to prevent the electrolyte reaching the higher temperatures at which the increased gassing occurs. These prior art prismatic housings add either or both of: considerable packaging bulk; and/or considerable cost in materials and/or manufacturing complexity. The design of element 9 and housing 3 used in the embodiment described above has been found to accommodate the pressure build-up in cavity 8 that occurred during a simulated reflow process and during a simulated operational lifetime of device 1.

Reference is now made to FIG. 18 where there is illustrated a flowchart of an exemplary method for manufacturing device 1. At step 201, predetermined proportions of carbon particles and a binder are combined and mixed with a liquid to form a substantially homogenous slurry. At step 202, a 20 microns thick elongate aluminium sheet is cleaned and allowed to dry at room temperature before being spiral wound into a coil. The dried sheet is then progressively uncoiled and fed to a coating station where it is coated across its width with a thin layer of the slurry containing a liquid, a mixture of carbon particles and a binder. The aluminium sheet is immediately advanced to a drying station, which includes a drying oven, to remove considerable amounts of the liquid from the mixture of carbon particles and binder. This drying leads to the formation of a carbon-based layer on the aluminium sheet having a thickness of 20 microns. In other embodiments, the carbon-based layer has a different thickness. The aluminium sheet is then re-coiled and left in a low moisture, clean environment and allowed to dry more thoroughly.

In an embodiment, activated carbon particles include activated carbons with a surface area of between 1,200 m²/g and 3,000 m²/g. In an embodiment the activated carbons have a particle size D50 between 3 μm and 10 μm and a D10>1 μm and a D90<30 μm. In an embodiment the activated carbon is a microporous carbon where more than 50% of the pore volume is less than 2 nm in size. Examples of suitable commercially available microporous activated carbons are MSP20 (Kansai Coke), MSC-30 (Kansai Coke), FAR01X (Kansai Coke), YP-80F (Kuraray), RP-25 (Kuraray), RP-20 (Kuraray), NY1151 (Kuraray Chemical Co., Ltd), NK261H (Kuraray), HDLC 20B STUW (Haycarb PLC), DLC 30 (Haycarb PLC), DLC 20P (Haycarb PLC), HCE-201 (Haycarb PLC), HCE-202 (Haycarb PLC), ACS20 (China Steel Chemical Corporation), ACS25 (China Steel Chemical Corporation), Yec-200E (IHUAN Carbon), YEC-8A (IHUAN Carbon), YEC-8B (IHUAN Carbon), Y-Carbon (Y-Carbon Inc.), ZL-302 (Huzhou Sensheng Activated Carbon Co., Ltd), MCSP 2005 (Calgon Mitsubishi Chemical Corporation), MCSP 1805A (Calgon Mitsubishi Chemical Corporation), and MCSP 1805-1 (Calgon Mitsubishi Chemical Corporation).

In an embodiment, the activated carbon can be classified as a mesoporous carbon where more than 50% of the pore volume has a pore size greater than 2 nm. Examples of suitable commercially available mesoporous carbons are P2-15 (EnerG2), MSA-20 (Kansai Coke and Chemicals), YP-50F (Kuraray), NY1251H (Kuraray), YPS (Kuraray), ACS15 (China Steel Chemical Corporation), TDA 60 (TDA Research), SO-15A (TDA Research), and ACC (Xiamen All Carbon Corporation).

The conducting particles present in the carbon-based electrode matrix facilitate efficient electron transport. Typical conducting particles used in an EDLC are carbon black. Carbon blacks typically have a sub-micron primary particle size between 10 nm to 100 nm. Carbon black particles often aggregate and require high shear to disperse them sufficiently in an electrode slurry. Examples of suitable carbon blacks are Printex carbon black such as L6 (Orion Carbons), PRINTEX® kappa 100 (Orion Engineered Carbons), PRINTEX® XE2 (Orion Engineered Carbons), ENSACO 150G (IMERYS), ENSACO 210G (IMERYS), ENSACO 250G (IMERYS), ENSACO 250F (IMERYS), ENSACO 260G (IMERYS), ENSACO 350G (IMERYS), Super C65 (IMERYS), LITX® HP (CABOT), LITX300 (CABOT), LITX200 (CABOT), VXC72R (CABOT), BP 700 (CABOT), BP 2000 (CABOT), SC2A (CABOT), TPX1278 (CABOT), Lump Black (Degussa), Ketjenblack EC300J (Akzo Noble), Ketjenblack EC600JD (Akzo Noble), E-MM-198G (Timcal), and Super P (Timcal).

In some embodiments both surfaces of the aluminium sheet are coated simultaneously with the slurry. In other embodiments, the coating operation is segmented, in that one surface is coated and, following drying, the opposite surface is coated. In further embodiments, the aluminium sheet is only coated on one of the surfaces.

At step 202, the re-coiled aluminium sheet is placed in a slitting station where the sheet is uncoiled and cut transversely to define a substantially rectangular and longitudinally elongate sheet portion that is separated from the coil. The longitudinal length of the sheet portion is determined by the required length of the electrode in device 1. This portion is then slit along a longitudinal path that is transversely offset by 7 mm from an elongate longitudinal edge of the portion to remove from the sheet portion a sheet segment. The sheet segment defines elongate double-sided carbon-based electrode 11 for device 1. The longitudinal slitting is repeated with the next transverse offset being made from the new edge created by the immediately preceding slitting operation to define elongate double-sided carbon-based electrode 12. The slitting operation occurs repeatedly until all or substantially all of the sheet portion is converted into electrodes, and then a further sheet portion is removed from the coil and the slitting process re-commenced. While such slitting is affected mechanically with a blade or blades, in an embodiment the sheet segmentation is performed by another form of cutting, such as laser cutting.

Once electrodes 11 and 12 have been produced, they are advanced to a connection station at step 204 where they are fixedly electrically connected to respective terminals 17 and 18. For device 1, the connection between each terminal and the respective electrode includes two separate and spaced apart connection points. In particularly, face 38 of end 19 of terminal 17 is abutted against one of the surfaces of electrode 11 at a predetermined longitudinal position and with axis 39 substantially normal to axis 4. End 19 is then pierced with two spaced apart circular punches that first contact face 37 and then advance through end 19 and the adjacent electrode 11. This operation creates two spaced apart radial formations that each extends from end 19, through electrode 11 and beyond the opposite face of electrode 11. The radial formations are flattened and move into engagement with the opposite face of electrode 11 and, hence establishes the required captive mechanical and electrical contact between electrode 11 and terminal 17. A similar operation is performed with electrode 12 and terminal 18. In other embodiments, a different number of connection points are created. In further embodiments, use is made of a different number of connection points, or other forms of connections and/or connection points.

The electrodes 11 and 12, with respective terminals 17 and 18 attached, are then at step 205, spiral wound about axis 4 together with intermediate sheets 13 and 14. The winding process uses a generally cylindrical mandrel that extends along axis 4 and which has an effective diameter of 4 mm. The mandrel includes two axially extending mandrel pieces having semi-circular cross sections. The flat portions of the mandrel pieces are opposed and define jaws for receiving and clamping the inner end of each of sheets 13 and 14. Once those ends are received and retained in the jaws, the sheets are tensioned and the mandrel rotated through two or three revolutions to form a hollow cylindrical central core for element 9 with the inner ends of sheets 13 and 14. The tension on the sheets is then released and electrodes 11 and 12 are alternated with sheets 13 and 14. The tension is reapplied such that electrodes 11 and 12 are also subject to the same tension. The mandrel is again rotated to affect a progressive winding of the electrodes and the separator sheets about the core at a substantially uniform tension.

The final winding of sheet 14 extends circumferentially beyond the outer edge 72 of sheet 13 and adhesive strip 77 is applied to secure end 75 of sheet 14 to the underlying and immediately preceding winding of sheet 14. The mandrel pieces are then moved radially away from each other slightly to release the clamping force on the inner ends of sheets 13 and 14. The mandrel pieces are then withdrawn from the core by progressing the mandrel axially relative to element 9. This leaves a hollow central axial aperture in element 9.

In other embodiments, the mandrel has a different effective diameter. In further embodiments the mandrel includes a slot for receiving and retaining the inner ends of sheets 13 and 14 in an interference fit rather than a clamping engagement. In still further embodiments, the mandrel includes a non-circular cross section and is removably complementarily received in an aperture of a reel to which the inner ends of sheets 13 and 14 are attached. At the end of the winding process, the reel is removed from the mandrel and remains with element 9.

At the completion of step 205, the substantially cylindrical element 9 has been manufactured.

Element 9 is advanced to the filling station where at step 206 it is inserted into cavity 8 of the still open-ended housing 3. This station then establishes a negative pressure, low humidity and raised temperature environment for the combination of element 9 and housing 3 to reduce any residual liquids, and particular to remove residual water molecules. A predetermined dose of the electrolyte is then placed into cavity 8 and is absorbed by the separator sheets 13 and 14 and moves into the voids in the carbon-based electrodes to wet those electrodes.

While still at the filling station, and while still being subject to one or more of the negative pressure, low humidity and raised temperature, lid 15 is advanced at step 207 relatively toward opening 7 along axis 4 such that ends 20 of terminals 17 and 18 are received by and then extend through respective apertures 33 and 34. Lid 15 continues to be advanced along axis 4 relative to housing 3 until ferrules 41 are received within apertures 33 and 34 and faces 42 are engaged in an interference fit with the adjacent surfaces of lid 15. At this point, face 30 of lid 15 has progressed through opening 7 and lies within cavity 8.

At step 208, the above assembly of parts is progressed to the forming station for the first forming operation and the second forming operation, which have been described above, to seal opening 7.

At step 209, base 51 is advanced along axis 4 relative to element 9 such that ends 20 of terminals 17 and 18 are received in respective apertures 53 and 54. Base 51 is then advanced further along axis 4 relative to element 9 such that ends 20 extend axially through and beyond base 51, and base 51 abuts end 5 of housing 3. Ends 20 of terminals 17 and 18 are then plastically deformed normally to faces 45 and 46 such that ends 20 extend substantially normally to both ends 19 and axis 39. The resultant configuration of terminals 17 and 18 is to captively retain base 51 in engagement with end 5. Moreover, the deformation of ends 20 of terminals 17 and 18 is such that they extend away from each other and faces 46 and 45 are respectively available to be presented for abutment with electrical pads 56 on PCB 2.

Device 1 is then progressed at step 210 to a testing station where a series of electrical tests is undertaken to ascertain if the characteristics of the manufactured SMD EDLC device fall within the required tolerances and/or other required operational standards.

According to an embodiment of the invention there is provided a method of manufacturing device 1, being an electric double layer capacitor (EDLC) device for reflow soldering to PCB 2, and where the method includes:
(a) providing the substantially cylindrical malleable housing 3 having opening 7 and cavity 8 that extends away from opening 7;
(b) plastically deforming housing 3 to define a sealing surface adjacent to opening 7;
(c) plastically deforming housing 3 to define a retention formation in the form of flange 28;
(d) spiral winding two carbon-based electrodes 11 and 12 together with a separator in the form of two separator sheets 13 and 14 to provide the substantially cylindrical capacitor element 9, wherein the separator sheets 13 and 14 maintain electrodes 11 and 12 in a spaced apart and opposed configuration;
(e) receiving element 9 in cavity 8;
(f) providing an electrolyte within cavity 8 for allowing ionic conduction between electrodes 11 and 12;
(g) providing a sealing element in the form of lid 15 for seating against the sealing surface for sealing opening 7, wherein flange 28 maintains the seating of lid 15; and
(h) providing two terminals 17 and 18, each of which extends between a first end 19 disposed in cavity 8 and a second end 20 disposed externally to cavity 8, wherein: ends 19 are electrically connected to respective electrodes 11 and 12; and terminals 17 and 18 extend through opening 7 such that ends 20 are available for electrical connection to PCB 2.

The above embodiments of the invention have been developed for surface mount technology applications and are applicable to a wide range of: electrical devices incorporating EDLC surface mount devices; to platforms using one or more of those electrical devices; and systems making use of one or more of those devices or one or more of those platforms. Examples of electrical devices include computing devices such as desktop computers, servers, controllers, laptop computers, tablet computers, and the like. Within such computing devices, the SMD EDLC device may be more specifically included in an electrical device such as a graphics card, a memory card, the motherboard, a computer peripheral device or any other electrical circuit within the electrical device or the peripheral device. Other electrical devices to which the embodiments of the invention are advantageously applied include: communications devices such as smartphones, cellular telephones, other cellular devices, or the like; control devices such pump controllers, motor controllers, power management controllers, and the like; remote monitoring devices; asset tracking devices; power train control for electric vehicles or vehicles making use of internal combustion engines; accessories, such as key fobs, for vehicles; control devices for e-locks and the like; wireless handheld devices such as point-of-sale devices; scanning devices; measurement devices; wireless remote control devices; smart meters or other such fixed meters; wearable technology devices such as smartwatches and health monitoring patches; IoT devices; wireless sensors; and others.

The electrical devices mentioned above are able to be used on, in or by a broad range of platforms, whether mobile or fixed. These platforms include, by way of example: land-based vehicular platforms (whether making use of a propulsion system powered by internal combustion, electrical energy, or otherwise); aircraft platforms, including drones; computing platforms; monitoring platforms; military platforms; communications platforms; marine platforms, both moveable and fixed; wearable technology platforms; and others.

The electrical devices and the platforms mentioned above are able to be used on, in or by a broad range of systems such as: telecommunications systems; server systems, including single servers, distributed server systems, server farms, and the like; control systems such as fleet management systems, building management systems, manufacturing systems and the like; and others.

It should be appreciated that in the above description of exemplary embodiments of the invention various features of the invention are sometimes grouped together in a single embodiment, Figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those skilled in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Similarly, it is to be noticed that the term “connected”, when used in this specification and, particularly, in the claims, should not be interpreted as being limited to direct connections only. The terms “connected”, along with its derivatives, may be used. It should be understood that these terms are not intended as synonyms for each other. Thus, the scope of the expression “a device A connected to a device B” should not be limited to devices or systems where an output or element of device A is directly connected to an input or element of device B. It means that there exists a functional path between an output of A and an input of B which may be a path including other devices or means. “Coupled” may mean that two or more elements are either in direct physical and/or electrical contact, or that the two or more elements are not in direct contact with each other but yet still co-operate or interact with each other to provide the defined connection.

Thus, while there has been described what are believed to be the preferred embodiments of the invention, those skilled in the art will recognize that other and further modifications may be made thereto without departing from the spirit of the invention, and it is intended to claim all such changes and modifications as falling within the scope of the invention.

1. An electric double layer capacitor (EDLC) device for reflow soldering to a printed circuit board (PCB), the device including:
a housing for defining an opening and a cavity that extends away from the opening;
a substantially cylindrical capacitor element for being received in the cavity, the element including two carbon-based electrodes and a separator that is spiral wound together with the electrodes, wherein the separator maintains the electrodes in a spaced apart and opposed configuration;
an electrolyte within the cavity for allowing ionic conduction between the electrodes;
a sealing element for sealing the opening; and
two terminals, each of which extends between a first end disposed in the cavity and a second end disposed externally to the cavity, wherein: the first ends are electrically connected to the respective electrodes; and the terminals extend through the opening such that the second ends are available for electrical connection to the PCB.

2. The EDLC device according to claim 1, wherein the PCB includes a PCB surface to which the device is to be mounted and the device includes a base having a first face for opposing the PCB surface, and the terminals extend relative to the base such that, in use, the second ends are substantially parallel with the PCB surface.

3. The EDLC device according to claim 2, wherein the terminals extend through the base.

4. The EDLC device according to claim 2, wherein the terminals extend along the base.

5. The EDLC device according to claim 2, wherein the terminals captively retain the base to the housing.

6. The EDLC device according to claim 2, wherein, in use, the base is disposed between the housing and the PCB surface.

7. The EDLC device according to claim 2, wherein the base includes conductive portions that, in use, are disposed adjacent to the terminals.

8. The EDLC device according to claim 1, wherein the sealing element provides a compression seal.

9. The EDLC device according to claim 8, wherein the housing includes a malleable sidewall that is plastically deformed to define a sealing surface for the compression seal.

10. The EDLC device according to claim 9, wherein the malleable sidewall includes aluminium, aluminium alloy or stainless steel.

11. The EDLC device according to claim 1, wherein at least one of the electrodes includes a high surface area carbon-based material.

12. The EDLC device according to claim 11, wherein the carbon-based material includes mesoporous carbon particles.

13. The EDLC device according to claim 1, wherein at least one of the electrodes includes a binder that is stable to at least 200° C.

14. The EDLC device according to claim 1, wherein the electrolyte is an organic electrolyte having, at 1 atm, a boiling point of greater than 200° C.

15. The EDLC device according to claim 1, having a rated voltage of between 2 to 4 Volts.

16. The EDLC device according to claim 2, wherein at least one of the electrodes includes a high surface area carbon-based material.

17. The EDLC device according to claim 16, wherein the carbon-based material includes mesoporous carbon particles.

18. The EDLC device according to claim 2, wherein at least one of the electrodes includes a binder that is stable to at least 200° C.

19. The EDLC device of claim 1, wherein the EDLC device has an initial ESR (ESR₁), wherein:
the housing has a housing temperature (T_{H});
after T_{H} has followed a predetermined thermal profile, the device has a second ESR (ESR₂),
wherein:
$${ESR}_{2} \geq {ESR}_{1} ; and \frac{100 * ( {ESR}_{2} - {ESR}_{1} )}{{ESR}_{1}} \leq 500 ;$$
and
the predetermined thermal profile includes a temperature threshold (T_{T}) of at least 180° C. and a threshold duration (t_{D}), where 25 seconds≤t_{D}≤40 seconds.

20. The EDLC device of claim 1, wherein the EDLC device has an initial ESR (ESR₁), wherein:
the housing has a housing temperature (T_{H});
after T_{H} has followed a predetermined thermal profile, the device has a second ESR (ESR₂),
wherein:
$${ESR}_{2} \geq {ESR}_{1} ; and \frac{100 * ( {ESR}_{2} - {ESR}_{1} )}{{ESR}_{1}} \leq 100 ;$$
and
the predetermined thermal profile includes a temperature threshold (T_{T}) of at least 180° C. and a threshold duration (t_{D}), where 25 seconds≤t_{D}≤40 seconds.
